(19) United States
(12) Patent Application Publication
(10) Pub. No.: US 2006/0141287 A1
(43) Pub. Date: Jun. 29, 2006

(54) OLEDs with improved operational lifetime

(75) Inventors: Kevin P. Klubek, West Henrietta, NY (US); Viktor V. Jarikov, Rochester, NY (US); Liang-Sheng Liao, Rochester, NY (US); Christopher T. Brown, Rochester, NY (US); Ching W. Tang, Rochester, NY (US)

Correspondence Address: Pamela R. Crocker;Patent Legal Staff, Eastman Kodak Company, 343 State Street, Rochester, NY, 14650-2201, US

(73) Assignee: Eastman Kodak Company

(21) Appl. No.: 11/357,310

(22) Filed: Feb. 17, 2006

Related U.S. Application Data
(63) Continuation-in-part of application No. 10/921,603, filed on Aug. 19, 2004.

(51) Int. Cl. H01L 51/54; H05B 33/12

(52) U.S. Cl. 428/690; 428/917; 428/212; 313/504; 313/506; 257/E51.026

(57) ABSTRACT

An organic light-emitting device includes a substrate, an anode and a cathode disposed over the substrate, and a light-emitting layer disposed between the anode and the cathode wherein the light-emitting layer includes a host and at least one dopant. The host of the light-emitting layer is selected to include a solid organic material including a mixture of at least two components wherein the first host component is an organic compound capable of transporting electrical charges and also forms an aggregate, and the second component of the mixture is an organic compound capable, of transporting electrical charges and, upon mixing with the first host component, is capable of forming a continuous and substantially pin-hole-free layer. The dopant of the light-emitting layer is selected to collect excitons and produce colored light, and an electron-transporting layer is disposed between the light-emitting layer and the cathode for providing improved electron injection and transport.

### CROSS REFERENCE TO RELATED APPLICATIONS

This application is a continuation-in-part of commonly-assigned U.S. patent application Ser. No. 10/921,603 filed Aug. 19, 2004. Reference is made to commonly assigned U.S. patent application Ser. No. 10/690,940 filed Oct. 22, 2003 by Tukaram K. Hatwar, et al., entitled “A Stabilized White-Light-Emitting OLED Device”; the disclosure of which is herein incorporated by reference.

### FIELD OF THE INVENTION

The present invention relates to organic light-emitting diode devices and more particularly to the design of the composition of the organic layers for improvements in operational lifetime.

### BACKGROUND OF THE INVENTION

Organic light-emitting diodes (OLED), also known as organic electroluminescent (EL) devices, are a class of electronic devices that emit light in response to an electrical current applied to the device. The structure of an OLED device generally includes an anode, an organic EL medium, and a cathode. The term, organic EL medium, herein refers to organic materials or layers of organic materials disposed between the anode and the cathode in the OLED device. The organic EL medium can include low molecular weight compounds, high molecular weight polymers, oligomers of low molecular weight compounds, or biomaterials, in the form of a thin film or a bulk solid. The medium can be amorphous or crystalline.

Organic electroluminescent media of various structures have been described in the prior art. Dresner, in RCA Review, 30, 322 (1969), describe a medium comprising a single layer of anthracene film. Tang et al., in Applied Physics Letters, 51, 913 (1987), Journal of Applied Physics, 65, 3610 (1989), and commonly assigned U.S. Pat. No. 4,769,292, report an EL medium with a multilayer structure of organic thin films, and demonstrated highly efficient OLED devices using such a medium. In some OLED device structures the multilayer EL medium includes a hole-transporting layer adjacent to the anode, an electron-transporting layer adjacent to the cathode, and disposed in between these two layers, a light-emitting layer. Furthermore, in some preferred device structures, the light-emitting layer is constructed of a doped organic film comprising an organic material as the host and a small concentration of a fluorescent compound as the dopant.

Improvements in EL efficiency, chromaticity, and lifetime have been obtained in these doped OLED devices by selecting an appropriate dopant-host composition. The dopant, being the dominant emissive center, is selected to produce the desirable EL colors. Examples of the doped light-emitting layer reported by Tang et al. in commonly assigned U.S. Pat. No. 4,769,292 and by Chen et al. in commonly assigned U.S. Pat. No. 5,908,581 are tris(8-quinolinol)-aluminum (Alq₃) host doped with coumarin dyes for green emitting OLEDs, and Alq₃ doped with 4-dicyanomethylene-4H-pyrans (DCMs) for orange-red emitting OLEDs. Shi et al., in commonly assigned U.S. Pat. No. 5,593,788, disclose that a long operational life was obtained in an OLED device by using a quinacridone compound as the dopant in an Alq₃ host. Bryan et al., in commonly assigned U.S. Pat. No. 5,141,671, disclose a light-emitting layer containing perylene or a perylene derivative as a dopant in a blue emitting host. They showed that a blue emitting OLED device with an improved operational lifetime was obtained. In both disclosures, the incorporation of selected fluorescent dopants in the light-emitting layer is found to substantially improve the overall OLED device performance parameters.

Co-doping of the light-emitting layer with anthracene derivatives can result in devices with better lifetime. Doping the hole-transporting layer with materials that impede hole-transporting and co-doping hole-transporting materials into electron-transporting Alq₃ leads to the improved device lifetimes, Popovic et al., Thin Solid Films, 363, 6 (2000); SPIE, 68, 3476 (1998).

The most common formulation of the doped light-emitting layer includes only a single dopant in a host matrix. However, in a few instances, incorporation of more than one dopant in the light-emitting layer was found to be beneficial in improving lifetime. Using a light-emitting layer containing rubrene, a yellow emitting dopant, and DCJ, 4-(dicyanomethylene)-2-methyl-6-[2-(4-julolidyl)ethenyl]-4H-pyran, a red emitting dopant, in an Alq₃ host it is possible to produce a red emitting OLED device with improved operational lifetime, Hamada et al. in Applied Phys. Lett., 75, 1682 (1999) and U.S. Pat. No. 6,387,546. Here rubrene functions as a co-dopant in mediating energy transfer from the Alq₃ host to the DCJ emitter. Generally, in dual dopant systems, it has been noted that the operational lifetime tends to increase compared to that of the single dopant systems.

Hamada et al. also report, in U.S. Patent Application Publication 2004/0066139 A1, the use of a host material, such as NPB (N,N′-Di(naphthalene-1-yl)-N,N′-diphenyl benzidine), a light-emitting dopant such as DBzR (5,12-bis(4-(6-methylbenzothiazol-2-yl)phenyl)-6,11-diphenylnaphthacene), and a non-luminescent auxiliary dopant (i.e., an auxiliary dopant that does not emit light) such as tBuDPN (5,12-Bis(4-tert-butylphenyl)naphthacene) in an OLED device. An electron-injecting layer including LiF is also reported.

Hatwar et al., U.S. Pat. No. 6,475,648 describe a case where a host and three dopants are used in the light-emitting layer of an OLED device. For example, a combination of Alq₃, 2% DCJT-B (4-(dicyanomethylene)-2-(t-butyl)-6-[2-(4-julolidyl)ethenyl]-4H-pyran), 5% NPB, and 5% Rubrene is reported. In some cases LiF is also used as an electron-injecting layer adjacent to the cathode.

Another attempt to improve the efficiency of EL devices involves using a mixture of components in the light-emitting layer. H. Azia et al., U.S. Pat. Nos. 6,614,175, 6,392,250, 6,392,339, and U.S. Patent Application Publications 2003/0134146 A1 and 2002/0135296 A1 report an organic light-emitting device that includes a mixed region. For example, a mixed region composed of a mixture of a hole-transporting material, such as NPB, and an electron-transporting material, commonly Alq₃, and in some cases a low level of a dopant is present such as rubrene.

Commonly assigned U.S. Patent Application Publication 2003/0215668 A1, the disclosure of which is herein incorporated by reference, describes a light-emitting layer containing a host and a stabilizer, wherein the stabilizer contains at least 5 fused rings and exhibits a first triplet energy level below 130 kJ/mol.

Commonly assigned U.S. Patent Application Publication 2004/0076853 A1, the disclosure of which is herein incorporated by reference, describes host materials for a light-emitting layer comprising a mixture of at least two components wherein the first component of the mixture is an organic compound that is capable of transporting either electrons or holes or both and is capable of forming both a monomer state and an aggregate state and further is capable of forming the aggregate state either in the ground electronic state or in the excited electronic state.

A number of researchers have reported the use of a thin layer of metal located between the cathode and the light-emitting layer that acts as an electron-injecting layer and improves the efficiency of an EL device. For example, U.S. Pat. Nos. 6,563,262 and 6,340,537 report the use of a layer of metal oxide wherein said metal oxide is selected from the group including metal oxides, alkaline earth metal oxides, lanthanide metal oxides, and mixtures thereof. U.S. Pat. No. 6,483,236 describes a thin layer of an alkaline metal fluoride formed on the organic light-emitting layer.

Instead of using a thin layer of metal as an electron-injecting layer it is also known to use an organic layer that is doped with a metal. J. Kido and T. Matsumoto, Appl. Phys. Lett., 73, 2866 (1998) report improved efficiency by using such a metal doped organic layer. This layer can be used in an OLED as an electron-injecting layer at the interface between a metal cathode and an emitter layer. A lithium doped layer of tris-(8-hydroxyquinoline) aluminum (Alq₃) results in a low barrier height for electron injection and high electron conductivity of the lithium doped Alq₃ layer. This improves quantum efficiency.

T. Hasegawa et al, in WO 2003/044829, report a light-emitting element in which an organic compound layer, such as Alq₃, contains a carbonate, for example Cs₂CO₃ and Li₂CO₃, as a dopant, and is in substantially electrical contact with a cathode.

S. Forrest et al., in U.S. Pat. No. 6,639,357, describe highly transparent non-metallic cathode that comprises a metal-doped organic electron-injecting layer, which also functions as an exciton blocking or hole-blocking layer. This layer is produced by diffusing an ultra-thin layer of a highly electropositive metal such as Li throughout the layer.

Although EL efficiency, color, and lifetime have been improved significantly using doped light-emitting layers of various compositions, the problem of low operational lifetime persists. Insufficient lifetime presents the greatest obstacle for many desirable practical applications.

### SUMMARY OF THE INVENTION

It is an object of the present invention to provide OLED devices with improved operational lifetime.

These objects are achieved in an organic light-emitting device, comprising:

a) a substrate;

b) an anode and a cathode disposed over the substrate;

c) a light-emitting layer disposed between the anode and the cathode wherein the light-emitting layer includes a host and at least one dopant;

d) the host of the light-emitting layer being selected to include a solid organic material including a mixture of at least two components wherein:
i) the first host component is an organic compound that is capable of transporting electrical charges and also forms an aggregate; and
ii) the second host component is an organic compound that is capable of transporting electrical charges and upon mixing with the first host component is capable of forming a continuous and substantially pin-hole-free layer; and

e) the dopant of the light-emitting layer being selected to produce colored light; and

f) an electron-transporting layer disposed between the light-emitting layer and the cathode for providing improved electron injection and transport.

An advantage of the present invention is that it provides OLED devices suitable for long-life displays and lighting applications.

Another advantage of the present invention is that the OLED efficiency is improved without adversely reducing the purity of color of the emitted light.

### BRIEF DESCRIPTION OF THE DRAWINGS

The drawings are necessarily of a schematic nature, since the individual layers are too thin and the thickness differences of the various elements too great to permit depiction to scale or to permit convenient proportionate scaling.

FIG. 1 is a schematic structure of an OLED with an organic EL medium;

FIG. 2 is a schematic structure of an OLED with an organic EL medium;

FIG. 3 is a schematic structure of an organic EL medium in an OLED;

FIG. 4 is a schematic structure of an OLED with an organic EL medium; and

FIG. 5 shows the solution absorption and emission spectra for NPB dissolved in ethyl acetate.

### DETAILED DESCRIPTION OF THE INVENTION

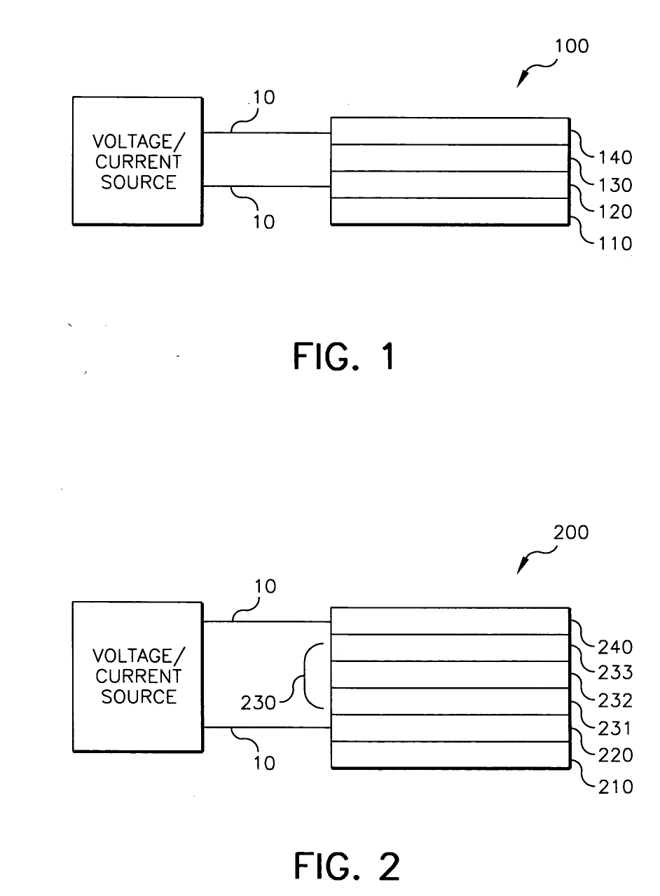

FIG. 1 illustrates the structure of an OLED device of the simplest construction practiced in the present invention. In this structure, the OLED device 100 includes an anode 120, an EL medium 130, and a cathode 140, disposed upon a substrate 110. In operation, an electrical current is passed through the OLED by connecting an external current or voltage source with electrical conductors 10 to the anode and the cathode, causing light to be emitted from the EL medium. The light can exit through either the anode or the cathode or both as desired and depending on their optical transparencies. The EL medium includes a single layer or a multilayer of organic materials.

FIG. 2 illustrates the structure of another OLED device of the present invention. In this structure, OLED device 200 includes a substrate 210 and an EL medium 230, disposed between anode 220 and cathode 240. EL medium 230 includes a hole-transporting layer 231 adjacent to the anode, an electron-transporting layer 233 adjacent to the cathode, and a light-emitting layer 232 disposed between the hole-transporting layer and the electron-transporting layer. In operation, an electrical current is passed through the OLED device by connecting an external current or voltage source with electrical conductors 10 to the anode and the cathode. This electrical current, passing through the EL medium, causes light to be emitted primarily from the light-emitting layer 232. Hole-transporting layer 231 carries the holes, that is, positive electronic charge carriers, from the anode to the light-emitting layer. Electron-transporting layer 233 carries the electrons, that is, negative electronic charge carriers, from the cathode to the light-emitting layer 232. The recombination of holes and electrons produces light emission, that is, electroluminescence, from the light-emitting layer 232.

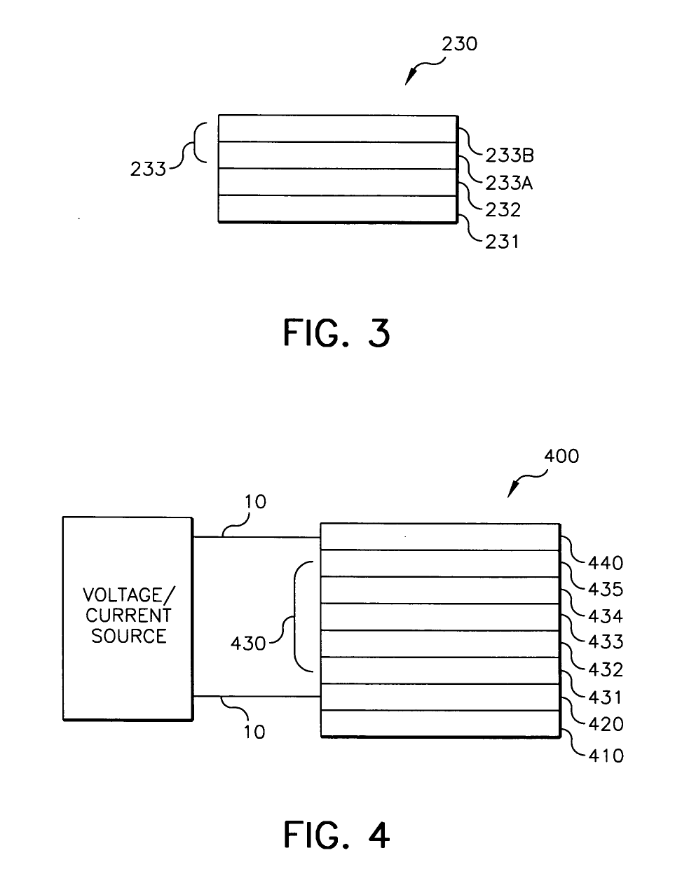

FIG. 3 is an illustration of one possible configuration of the EL medium 230 from OLED device 200. In this structure, electron transport layer 233 is divided into 2 separate sublayers. Sublayer 233A is adjacent to light-emitting layer 232 while sublayer 233B is adjacent to cathode 240 in OLED device 200. Dividing the electron transport layer into 2 separate sublayers permits the use of different materials in each layer. Consequently, device performance can be further optimized.

FIG. 4 illustrates yet another structure of an OLED device of the present invention. In this structure, OLED device 400 includes a substrate 410 and an EL medium 430 disposed between anode 420 and cathode 440. EL medium 430 includes a hole-injecting layer 431, a hole-transporting layer 432, a light-emitting layer 433, an electron-transporting layer 434, and an electron-injecting layer 435. Similarly to OLED device 200 of FIG. 2, the recombination of electrons and holes produces emission primarily from the light-emitting layer 433. The provision of the hole-injecting layer 431 and the electron-injecting layer 435 serves to reduce the barriers for carrier injection from the respective electrodes. Consequently, the drive voltage required for the OLED device can be reduced.

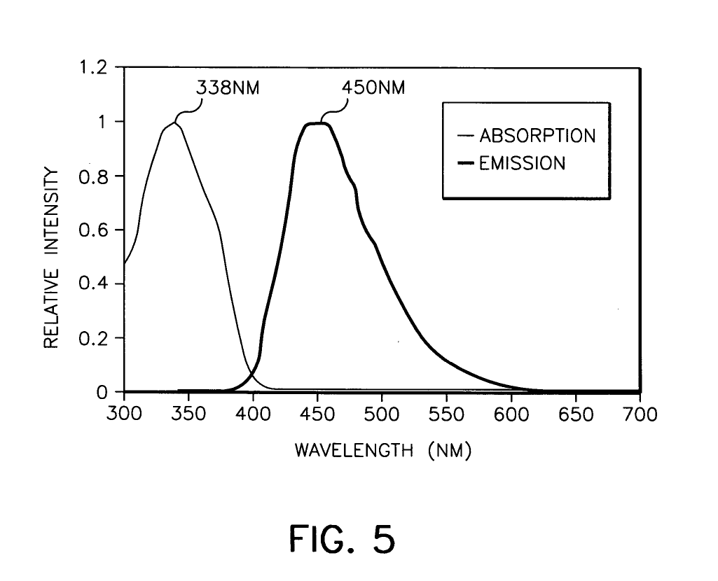

FIG. 5 shows the solution absorption and emission spectra for NPB dissolved in ethyl acetate. This figure illustrates how NPB is a material that does not form aggregates. The optical density was 0.13 at the excitation wavelength, which was set at the absorption maximum of 338 nm. The emission maximum was at 450 nm. The solution quantum yield was approximately 19%.

In a preferred embodiment of the present invention, the electron-transporting layer includes at least one alkali metal or alkaline earth metal. Alkali metals are metals of Group 1A on the periodic table. Alkaline earth metals are metals in Group 2A on the periodic table. In one preferred embodiment the alkali metal is Li. In another preferred embodiment, the alkali metal is Cs.

Suitably the alkali metal or alkaline earth metal is dispersed in the electron-transporting layer at a level of 0.01 to 40 volume %, and more preferably at a level of 0.1 to 35 volume %, and desirably at a level of 1.0 to 30 volume %. Depending on the alkali metal or alkaline earth metal chosen, the volume percentages that are most desirable are those that correspond to a molar ratio of alkali metal or alkaline earth metal to electron-transporting material in the electron-transporting layer between 0.1:1 to 2:1, respectively.

In one desirable embodiment the electron-transporting layer is further divided into at least two sublayers. In this case the sublayers can comprise the same electron-transporting material or different electron-transporting materials. At least one sublayer includes an alkali metal or alkaline earth metal. In one preferred embodiment, the alkali metal is Li. In another preferred embodiment, the alkali metal is Cs. Preferably, the sublayer including the alkali metal or alkaline earth metal is adjacent to the cathode. Preferably, the material of the sublayer adjacent to the light-emitting layer:
i) has a Lowest Unoccupied Molecular Orbital (LUMO) level equal to or lower than that of the second host component of the light-emitting layer;
ii) has a Highest Occupied Molecular Orbital (HOMO) level lower than those of the first and second host component of the light-emitting layer; and
iii) does not include an alkali metal or alkaline earth metal.

Desirably the electron-transporting layer comprises an oxinoid compound. Exemplary of contemplated oxinoid compounds are those satisfying the following structural formula: 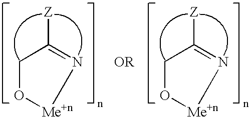
wherein:

Me represents a metal;

n is an integer of from 1 to 3; and

Z independently in each occurrence represents the atoms completing a nucleus having at least two fused aromatic rings.

From the foregoing it is apparent that the metal can be monovalent, divalent, or trivalent metal. The metal can, for example, be an alkali metal, such as lithium, sodium, rubidium, cesium, or potassium; an alkaline earth metal, such as magnesium, beryllium, strontium, barium, or calcium; or an earth metal, such as boron or aluminum, gallium, and indium. Generally any monovalent, divalent, or trivalent metal known to be a useful chelating metal can be employed.

Z completes a heterocyclic nucleus containing at least two fused aromatic rings, at least one of which is an azole or azine ring. Additional rings, including both aliphatic and aromatic rings, can be fused with the two required rings, if required. To avoid adding molecular bulk without improving on function the number of ring atoms is preferably maintained at 18 or less.

Illustrative of useful chelated oxinoid compounds and their abbreviated names are the following:
Tris(8-quinolinol)aluminum (Alq₃);
Bis(8-quinolinol)magnesium (MgQ₂);
Tris(8-quinolinol)gallium (GaQ₃); and
8-quinolinol lithium (LiQ).
   The list further includes InQ₃, ScQ₃, ZnQ₂, BeBq₂ (bis(10-hydroxybenzo-[h]quinolinato)beryllium), Al(4-MeQ)₃, Al(2-MeQ)₃, Al(2,4-Me₂Q)₃, Ga(4-MeQ)₃, Ga(2-MeQ)₃, Ga(2,4-Me₂Q)₃, and Mg(2-MeQ)₂. The list of oxinoid compounds further includes metal complexes with two bi-dentate ligands and one mono-dentate ligand, for example Al(2-MeQ)₂(X) where X is any aryloxy, alkoxy, arylcaboxylate, and heterocyclic carboxylate group. In one desirable embodiment the electron-transporting material comprises Alq₃.

Other electron-transporting materials suitable for use in the electron-transporting layer include various butadiene derivatives as disclosed in U.S. Pat. No. 4,356,429, various phenanthroline derivatives as disclosed in EP 564,224 and various heterocyclic optical brighteners as described in U.S. Pat. No. 4,539,507. Particularly useful phenanthroline derivatives are BPHEN and BCP

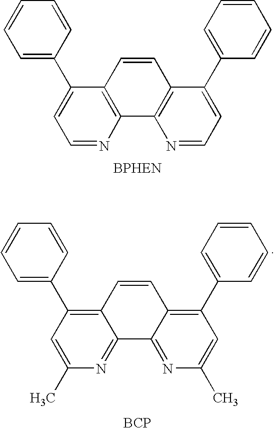

Benzazoles and triazines, for example see U.S. Pat. No. 6,225,467, are also useful electron transporting materials. One example of a particularly useful triazine is Triazine 1

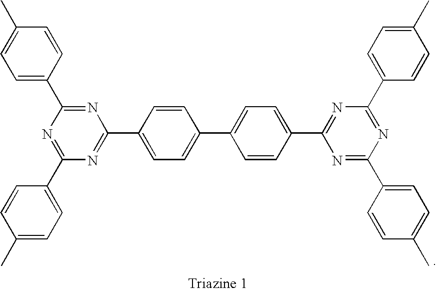

According to the present invention, new materials and new compositions that improve electron injection and electron transport in an OLED device while not adversely affecting operational lifetime will result in improved operational lifetime in OLED devices containing a light-emitting layer constructed according to the below specification.

An electron-transport material, disposed between the light-emitting layer(s) and the metallic cathode, which lowers or eliminates the barrier for electron injection from the cathode into the ETL and enhances electron transport across the layer is considered to be an improved electron-transport material. Examples of common cathode materials are: Mg:Ag alloy, LiF|Al, LiF|Ag, Li|Al, Li|Ag (where LiF or Li constitute a thin 1-10 Å electron-injection layer and Al or Ag constitute the cathode), Mg, Ca, and Ba. The light emitting layer(s) are discussed below.

The barrier reduction and the transport enhancement are determined with respect to the commonly employed ETL made of pure AlQ (Tris(8-quinolinol)aluminum) on top of which a common cathode of either Mg:Ag (20:1) alloy or LiF|Al is disposed. The barrier reduction and the transport enhancement are determined by testing a simple light-emitting device, wherein:
i″) the voltage drop across the ETL in the direction of the layer thickness is less than 0.007 V/Å at a drive current of 20 mA/cm² with Mg:Ag (20:1) cathode or less than 0.006 V/Å at a drive current of 20 mA/cm² with LiF|Al, Li|Al, LiF|Ag, or Li|Ag cathode; and
ii″) the electron-transport material enhances or at least does not significantly reduce (no more than 10-15%) the electroluminescent efficiency of the test device.

The test device has a simple structure: 1.1 mm glass|250 Å ITO|10 Å CFₓ|750 Å NPB|375 Å AlQ|375 Å test ETL material|2,100 Å Mg:Ag (20:1) or alternatively, in place of Mg:Ag alloy the cathode may be composed of a 5 Å LiF electron-injection layer and 1,000 Å Al. Also, in place of CFₓ one may use other materials to modify the anode surface, as described above: CuPc, DPQHC, F₄TCNQ, molybdenum oxide, FeCl₃, FeF₃, etc. Thus, the test material is compared to pure AlQ as the ETL material using this simple device structure. The prepared test devices must be stored and the testing must be conducted at room temperature.

To properly measure the voltage drop across the ETL in V/Å, a simple series of test devices needs to be produced where the only variable is the thickness of the ETL. The ETL thickness can be varied, for example, from 100 Å to 1,000 Å with several points in between. The plot of the drive voltage for these devices, e.g., at 20 mA/cm², vs. the ETL thickness, usually can be satisfactorily fitted with a straight line and the tangent of the angle formed by the fitted straight line and the x axis is the voltage drop across the ETL in V/Å. Making such a graph for neat AlQ as the ETL material results in the voltage drop across the ETL of 0.007 V/Å at a drive current of 20 mA/cm² with Mg:Ag (20:1) cathode and 0.006 V/Å at a drive current of 20 mA/cm² with LiF|Al, Li|Al, LiF|Ag, or Li|Ag cathode.

If one assumes that the relationship between the drive voltage and the ETL thickness is linear, then a qualitative answer may be obtained, to a first approximation, by comparing the drive voltages of two test devices—one having AlQ as the ETL material (reference device) and the other having the test ETL material. If the drive voltage for the latter is significantly (e.g. at least by 10%) lower than that for the former then the test ETL material will satisfy the V/Å requirement of this invention.

When constructing test devices, it is preferable to use a Mg:Ag cathode. If the alternative cathode of LiF|Al is chosen, one should be aware that the trends using LiF|Al cathode are not always quantitatively similar to those observed with the Mg:Ag cathode. This is because, as known in the art, Li metal is generated from LiF upon reaction with a cathode material such as Al. It is also known in the art that Li metal diffuses through a layer of some compounds, such as BPhen, BCP, and other phenanthroline compounds efficiently at room temperature, while diffusion of Li metal in AlQ is by far smaller. Hence, Li metal generated from LiF may spread throughout the entire thickness of the ETL, if the latter is composed of a phenanthroline compound, which essentially would be similar to the situation where the entire ETL is doped with Li metal. This in turn would lead to lower voltage drop across such ETL. The magnitude of reduction is subject to the ETL thickness, the amount of Li generated, and time and temperature of device storage and may lead to non-linear drive voltage—ETL thickness dependencies.

Let us consider a comparison at a single ETL thickness. The voltage drop across the ETL for the 375 Å BPhen|5 Å LiF|1,000 Å Al configuration is usually lower by ˜2 V at 20 mA/cm², than for the 375 Å BPhen|2,100 Å Mg:Ag configuration. Therefore, the same material, such as BPhen, can appear a better choice when tested with the LiF|Al cathode than when tested with Mg:Ag cathode. For reference, the voltage drop across the AlQ ETL is usually only ˜0.5 V lower for the 375 Å AlQ|5 Å LiF|1,000 Å Al configuration than for the 375 Å AlQ|2,100 Å Mg:Ag configuration.

According to the present invention, the light-emitting layer (either layer 232 of FIG. 2 or layer 433 of FIG. 4) is primarily responsible for the electroluminescence emitted from the OLED device. One of the most commonly used formulations for this light-emitting layer is an organic thin film including a host and one or more dopants. The host serves as the solid medium or matrix for the transport and recombination of charge carriers injected from the anode and the cathode. The dopant, usually homogeneously distributed in the host in small quantity, provides the emission centers where light is produced. As is well known in the art, the present invention uses a light-emitting layer including a host and a dopant. However, in the present case the host is a mixture having at least two components, each component having specific electronic properties. The selection of these host components and compatible dopant materials is in accordance with the following criteria:

1. The host is a solid organic thin film comprising a mixture of at least two components;

2. The first host component is:
a) an organic compound that is capable of transporting electrical charges;
b) capable of forming an aggregate;
c) capable of forming an aggregate either in the ground electronic state or in the excited electronic state;
d) capable of forming:
   i) an aggregate that results in an absorption or emission spectrum that is significantly different from that of the monomer; or
   ii) an aggregate whose presence results in a quantum yield of luminescence of the monomer being different relative to that of the monomer in the absence of the aggregate;

3. The second host component is an organic compound that is capable of transporting electrical charges and upon mixing with the first host component is capable of forming a continuous and substantially pin-hole-free layer; and

4. The dopant is an organic light-emitting compound capable of accepting the electronic excitation energy released from the recombination of charges in either the first or second host components, and emitting the electronic excitation energy as light.

In one embodiment the first host component constitutes at least 1 volume % of the light-emitting layer, more desirably at least 10 volume %, and preferably at least 25 volume % of the light-emitting layer.

Following the selection criteria of this invention, OLED devices constructed exhibit excellent operational lifetimes. These devices also possess high efficiencies and excellent color chromaticity. It is also noteworthy that the high efficiency remains constant over a large range of current densities. A distinct advantage over the prior art lies in the fact that it is explicitly shown that improved electron injection into and transport across the electron-transporting layer result in large increases in operational lifetime for these OLED devices, from 1.5 to 10 times depending on the exact configuration of the electron transporting layer. These lifetimes reach 15,000 to 100,000 hours upon continuous operation at 40 mA/cm² and 22° C. (room temperature) while the EL efficiency and color are at least not adversely affected and are often improved, and while the drive voltage is lowered. Another important advantage of the current invention is that the chromaticity remains essentially constant, independent of the current density or brightness. Thus, the problem of color shift with brightness in an OLED device is also eliminated.

Preferred materials for the first host component of the light-emitting layer of this invention include a class of compounds which, for the purpose of this invention, will be referred to as benzenoid compounds and N-, O-, Si-, B-, P-, and S-atom containing heterocyclic compounds. The benzenoid compounds comprise polycyclic aromatic hydrocarbons (PAH), combinations of two or more PAH which are chemically linked, and combinations of two or more PAH which are not chemically linked. Non-benzenoid aromatic hydrocarbons such as azulene and its derivatives are included as preferred materials for the first host component. Essentially any flat and rigid molecule, or one having a flat and rigid part, that has a propensity to undergo aggregation is included as a preferred material for the first host component of the light-emitting layer of this invention. Possible exceptions include compounds that undergo known unfavorable chemical reactions either thermally, photochemically, or upon electrochemical oxidation or reduction in an OLED device. For example, 1,3-diphenylisobenzofuran readily undergoes Diels-Alder reactions as well as rearrangement and condensation reactions; truxenes, fluorenes, and other compounds having Aryl-CH₂-Aryl′ or Aryl-CH(Aryl″)-Aryl′ bridges have labile hydrogen atoms; esters undergo dissociation and decarboxylation reactions, alcohols and acids undergo deprotonation. Another example of an exception that depends on the nature of the use of the material in an OLED device can include certain heterocyclic molecules such as imidazoles, triazoles, oxadiazoles, pyridines, phenanthrolines, and others, which are known to undergo certain chemical transformations in an OLED device upon their electrochemical oxidation (hole injection) that leads to short operational lifetimes. Another example of possible exception includes molecules containing chloro-, bromo-, or iodo-substituents, which upon electrochemical oxidation or reduction undergo possible cleavage or dissociation reactions that lead to short operational stabilities of an OLED device.

Benzenoid and heterocyclic compounds absorbing light in the UV, near UV, and visible region up to 450 nm are preferred materials for the first host component of a blue-emitting OLED device and blue-emitting layer of a white-emitting OLED device. Benzenoid and heterocyclic compounds absorbing light in the UV, near UV, and visible region up to 490 nm are preferred materials for the first host component of a blue-green-emitting OLED device and blue-green emitting layer of a white-emitting OLED device. Benzenoid and heterocyclic compounds absorbing light in the UV, near UV, and visible region up to 520 nm are preferred materials for the first host component of a green-emitting OLED device and green emitting layer of a white-emitting OLED device. Benzenoid and heterocyclic compounds absorbing light in the UV, near UV, and visible region up to 580 nm are preferred materials for the first host component of a yellow-orange-emitting OLED device and yellow-orange emitting layer of a white-emitting OLED device. Benzenoid and heterocyclic compounds absorbing light in the UV, near UV, and visible region up to 630 nm are preferred materials for the first host component of a red-emitting OLED device and red emitting layer of a white-emitting OLED device.

The list of simple PAH useful as building blocks and parent structures for benzenoid compounds or derivatives thereof, includes:
1. Benzene;
2. Naphthalene;
3. Phenanthrene;
4. Chrysene;
5. Anthracene;
6. Naphthacene;
7. Pentacene;
8. Hexacene;
9. Heptacene;
10. Pyrene;
11. Perylene;
12. Benzo[ghi]perylene;
13. Benzo[a]perylene;
14. Benzo[b]perylene;
15. Coronene;
16. Fluoranthene;
17. Fluorene;
18. Tetraphene;
19. Pentaphene;
20. Hexaphene;
21. Aceanthrylene;
22. Acepyrene;
23. Aceperylene;
24. Anthanthrene;
25. Indene;
26. Triphenylene;
27. Biphenyl;
28. Terphenyl;
29. Quarterphenyl;
30. Quinqephenyl;
31. Sexiphenyl;
32. Binaphthyl;
33. Picene;
34. Pyranthrene;
35. Bisanthrene (bisanthene);
36. Ovalene;
37. Peropyrene;
38. Triptycene; and
39. Phenalene.

The list of simple heterocycles useful as building blocks for heterocyclic compounds or derivatives thereof includes:
40. Pyrrole;
41. Pyrazole;
42. Imidazole;
43. 1,2,3-Triazole;
44. 1,2,4-Triazole;
45. 1,2-Dithiole;
46. 1,3-Dithiole;
47. 1,2-Oxathiole;
48. Isoxazole;
49. Oxazole;
50. Thiazole;
51. Isothiazole;
52. 1,2,4-Oxadiazole;
53. 1,2,5-Oxadiazole;
54. 1,3,4-Oxadiazole;
55. 1,2,3,4-Oxatriazole;
56. 1,2,3,5-Oxatriazole;
57. 1,2,3-Dioxazole;
58. 1,2,4-Dioxazole;
59. 1,3,2-Dioxazole;
60. 1,3,4-Dioxazole;
61. 1,2,5-Oxathiazole;
62. 1,3-Oxathiole;
63. Pyridine;
64. Pyridazine;
65. Pyrimidine;
66. Pyrazine;
67. 1,3,5-Triazine;
68. 1,2,4-Triazine;
69. 1,2,3-Triazine;
70. Furan;
71. Dibenzofuran;
72. Benzofuran;
73. Isobenzofuran;
74. Thiophene;
75. Dibenzothiophene;
76. Benzo[b]thiophene;
77. Benzo[c]thiophene;
78. Indole;
79. Pyrano[3,4-b]pyrrole;
80. Indazole;
81. Indoxazine;
82. Benzoxazole;
83. Quinoline;
84. Isoquinoline;
85. Cinnoline;
86. Quinazoline;
87. 1,8-Naphthyridine;
88. 1,7-Naphthyridine;
89. 1,6-Naphthyridine;
90. 1,5-Naphthyridine;
91. Benzoxazine;
92. Carbazole;
93. Xanthene;
94. Acridine;
95. Purine;
96. Dibenzo[f,h]quinoline (1-Azatriphenylene);
97. Dibenzo[f,h]quinoxaline (1,4-Diazatriphenylene);
98. Phenanthridine;
99. 1,7-Phenanthroline;
100. 1,10-Phenanthroline;
101. 4,7-Phenanthroline; and
102. Phenazine.

The list of building blocks as indicated above (1-102) can include alkyl, alkenyl, alkynyl, aryl, substituted aryl, silyl, ace, indeno, 1,2-benzo, 1,2-naphtho, 2,3-naphtho, 1,8-naphtho, 1,2-anthraceno, 2,3-anthraceno, 2,2′-BP, 4,5-PhAn, 1,12-TriP, 1,12-Per, 9,10-PhAn, 1,9-An, 1,10-PhAn, 2,3-PhAn, 1,2-PhAn, 1,10-Pyr, 1,2-Pyr, 2,3-Per, 3,4-FlAn, 2,3-FlAn, 1,2-FlAn, 3,4-Per, 7,8-FlAn, 8,9-FlAn, 2,3-TriP, 1,2-TriP, 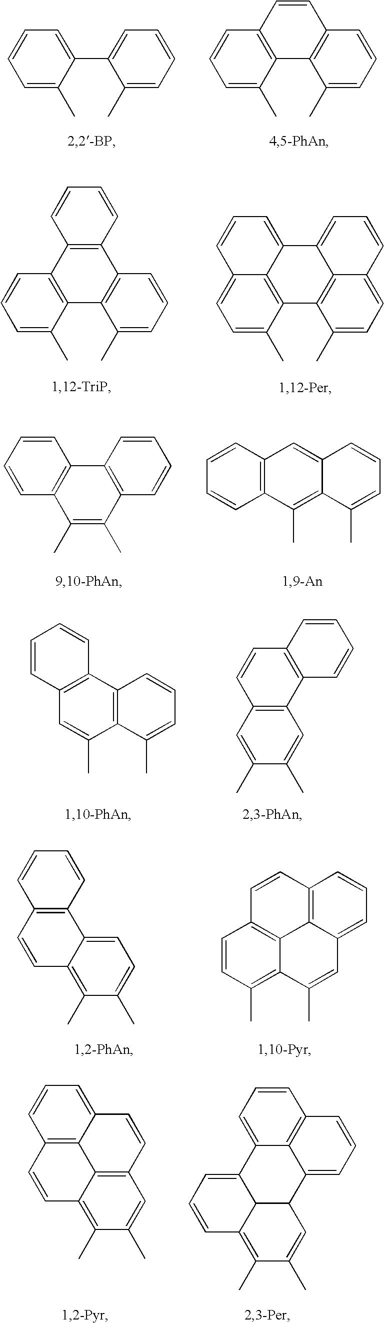 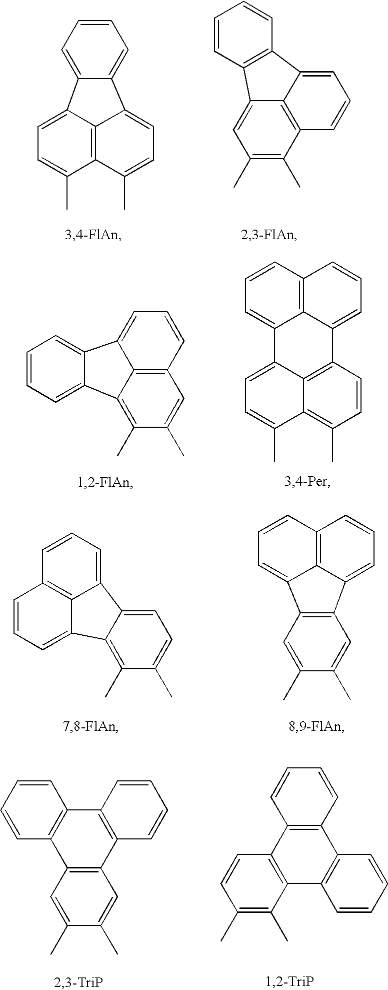
(where bonds that do not form a cycle indicate points of attachment), fluoro, cyano, alkoxy, aryloxy, amino, aza, oxo, thia, heterocyclic, keto, and dicyanomethyl or derivatives thereof as materials for the first host component of the luminescent layer of this invention.

A complete list of preferred benzenoid, PAH, and heterocyclic compounds or derivatives thereof can be found in commonly assigned U.S. Patent Application Publication 2004/0076853 A1 and commonly assigned U.S. patent application Ser. No. 10/691,326 filed Oct. 22, 2003 by Viktor V. Jarikov, et al., entitled “Aggregate Organic Light Emitting Diode Devices With Improved Operational Stability”, the disclosures of which are herein incorporated by reference.

Any of the above listed building blocks, and any benzenoid compounds formed by the combination of one or more of the above listed building blocks which may or may not be chemically linked, are useful as the first host component, and importantly, the compounds do not have to be film forming materials at room temperature. The mixture of the second host component and the first host component should be capable of forming continuous amorphous films.

Particularly preferred materials for the first host component of the light-emitting layer of this invention include benzenoid compounds of the following structures 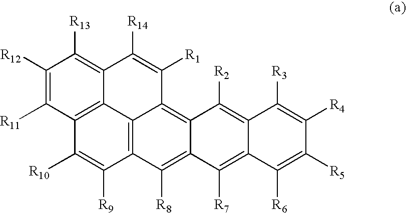
wherein:

substituents R₁ through R₁₄ are each individually hydrogen, fluoro, cyano, alkoxy, aryloxy, diarylamino, arylalkylamino, dialkylamino, trialkylsilyl, triarylsilyl, diarylalkylsilyl, dialkylarylsilyl, keto, dicyanomethyl, alkyl of from 1 to 24 carbon atoms, alkenyl of from 1 to 24 carbon atoms, alkynyl of from 1 to 24 carbon atoms, aryl of from 5 to 30 carbon atoms, substituted aryl, heterocycle containing at least one nitrogen atom, or at least one oxygen atom, or at least one sulfur atom, or at least one boron atom, or at least one phosphorus atom, or at least one silicon atom, or any combination thereof; or any two adjacent R₁ through R₁₄ substituents form an annelated benzo-, naphtho-, anthra-, phenanthro-, fluorantheno-, pyreno-, triphenyleno-, or peryleno-substituent or its alkyl or aryl substituted derivative; or any two R₁ through R₁₄ substituents form a 1,2-benzo, 1,2-naphtho, 2,3-naphtho, 1,8-naphtho, 1,2-anthraceno, 2,3-anthraceno, 2,2′-BP, 4,5-PhAn, 1,12-TriP, 1,12-Per, 9,10-PhAn, 1,9-An, 1,10-PhAn, 2,3-PhAn, 1,2-PhAn, 1,10-Pyr, 1,2-Pyr, 2,3-Per, 3,4-FlAn, 2,3-FlAn, 1,2-FlAn, 3,4-Per, 7,8-FlAn, 8,9-FlAn, 2,3-TriP, 1,2-TriP, ace, or indeno substituent or their alkyl or aryl substituted derivative; or 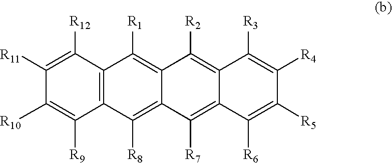
wherein:

substituents R₁ through R₁₂ are each individually hydrogen, fluoro, cyano, alkoxy, aryloxy, diarylamino, arylalkylamino, dialkylamino, trialkylsilyl, triarylsilyl, diarylalkylsilyl, dialkylarylsilyl, keto, dicyanomethyl, alkyl of from 1 to 24 carbon atoms, alkenyl of from 1 to 24 carbon atoms, alkynyl of from 1 to 24 carbon atoms, aryl of from 5 to 30 carbon atoms, substituted aryl, heterocycle containing at least one nitrogen atom, or at least one oxygen atom, or at least one sulfur atom, or at least one boron atom, or at least one phosphorus atom, or at least one silicon atom, or any combination thereof; or any two adjacent R₁ through R₁₂ substituents form an annelated benzo-, naphtho-, anthra-, phenanthro-, fluorantheno-, pyreno-, triphenyleno-, or peryleno-substituent or its alkyl or aryl substituted derivative; or any two R₁ through R₁₂ substituents form a 1,2-benzo, 1,2-naphtho, 2,3-naphtho, 1,8-naphtho, 1,2-anthraceno, 2,3-anthraceno, 2,2′-BP, 4,5-PhAn, 1,12-TriP, 1,12-Per, 9,10-PhAn, 1,9-An, 1,10-PhAn, 2,3-PhAn, 1,2-PhAn, 1,10-Pyr, 1,2-Pyr, 2,3-Per, 3,4-FlAn, 2,3-FlAn, 1,2-FlAn, 3,4-Per, 7,8-FlAn, 8,9-FlAn, 2,3-TriP, 1,2-TriP, ace, or indeno substituent or their alkyl or aryl substituted derivative; or 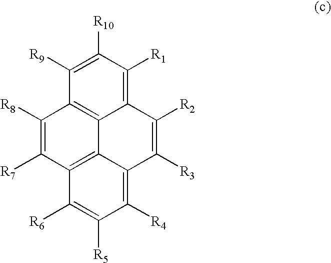
wherein:

substituents R₁ through R₁₀ are each individually hydrogen, fluoro, cyano, alkoxy, aryloxy, diarylamino, arylalkylamino, dialkylamino, trialkylsilyl, triarylsilyl, diarylalkylsilyl, dialkylarylsilyl, keto, dicyanomethyl, alkyl of from 1 to 24 carbon atoms, alkenyl of from 1 to 24 carbon atoms, alkynyl of from 1 to 24 carbon atoms, aryl of from 5 to 30 carbon atoms, substituted aryl, heterocycle containing at least one nitrogen atom, or at least one oxygen atom, or at least one sulfur atom, or at least one boron atom, or at least one phosphorus atom, or at least one silicon atom, or any combination thereof; or any two adjacent R₁ through R₁₀ substituents form an annelated benzo-, naphtho-, anthra-, phenanthro-, fluorantheno-, pyreno-, triphenyleno-, or peryleno-substituent or its alkyl or aryl substituted derivative; or any two R₁ through R₁₀ substituents form a 1,2-benzo, 1,2-naphtho, 2,3-naphtho, 1,8-naphtho, 1,2-anthraceno, 2,3-anthraceno, 2,2′-BP, 4,5-PhAn, 1,12-TriP, 1,12-Per, 9,10-PhAn, 1,9-An, 1,10-PhAn, 2,3-PhAn, 1,2-PhAn, 1,10-Pyr, 1,2-Pyr, 2,3-Per, 3,4-FlAn, 2,3-FlAn, 1,2-FlAn, 3,4-Per, 7,8 -FlAn, 8,9-FlAn, 2,3-TriP, 1,2-TriP, ace, or indeno substituent or their alkyl or aryl substituted derivative; or 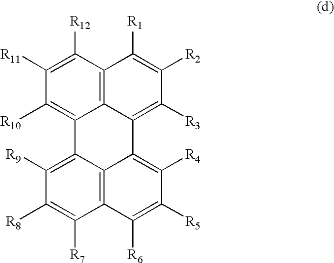
wherein:

substituents R₁ through R₁₂ are each individually hydrogen, fluoro, cyano, alkoxy, aryloxy, diarylamino, arylalkylamino, dialkylamino, trialkylsilyl, triarylsilyl, diarylalkylsilyl, dialkylarylsilyl, keto, dicyanomethyl, alkyl of from 1 to 24 carbon atoms, alkenyl of from 1 to 24 carbon atoms, alkynyl of from 1 to 24 carbon atoms, aryl of from 5 to 30 carbon atoms, substituted aryl, heterocycle containing at least one nitrogen atom, or at least one oxygen atom, or at least one sulfur atom, or at least one boron atom, or at least one phosphorus atom, or at least one silicon atom, or any combination thereof; or any two adjacent R₁ through R₁₂ substituents form an annelated benzo-, naphtho-, anthra-, phenanthro-, fluorantheno-, pyreno-, triphenyleno-, or peryleno-substituent or its alkyl or aryl substituted derivative; or any two R₁ through R₁₂ substituents form a 1,2-benzo, 1,2-naphtho, 2,3-naphtho, 1,8-naphtho, 1,2-anthraceno, 2,3-anthraceno, 2,2′-BP, 4,5-PhAn, 1,12-TriP, 1,12-Per, 9,10-PhAn, 1,9-An, 1,10-PhAn, 2,3-PhAn, 1,2-PhAn, 1,10-Pyr, 1,2-Pyr, 2,3-Per, 3,4-FlAn, 2,3-FlAn, 1,2-FlAn, 3,4-Per, 7,8-FlAn, 8,9-FlAn, 2,3-TriP, 1,2-TriP, ace, or indeno substituent or their alkyl or aryl substituted derivative; or 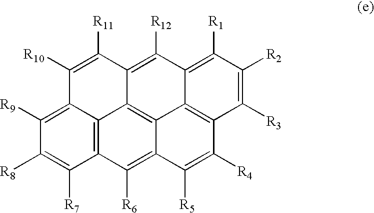
wherein:

substituents R₁ through R₁₂ are each individually hydrogen, fluoro, cyano, alkoxy, aryloxy, diarylamino, arylalkylamino, dialkylamino, trialkylsilyl, triarylsilyl, diarylalkylsilyl, dialkylarylsilyl, keto, dicyanomethyl, alkyl of from 1 to 24 carbon atoms, alkenyl of from 1 to 24 carbon atoms, alkynyl of from 1 to 24 carbon atoms, aryl of from 5 to 30 carbon atoms, substituted aryl, heterocycle containing at least one nitrogen atom, or at least one oxygen atom, or at least one sulfur atom, or at least one boron atom, or at least one phosphorus atom, or at least one silicon atom, or any combination thereof; or any two adjacent R₁ through R₁₂ substituents form an annelated benzo-, naphtho-, anthra-, phenanthro-, fluorantheno-, pyreno-, triphenyleno-, or peryleno-substituent or its alkyl or aryl substituted derivative; or any two R₁ through R₁₂ substituents form a 1,2-benzo, 1,2-naphtho, 2,3-naphtho, 1,8-naphtho, 1,2-anthraceno, 2,3-anthraceno, 2,2′-BP, 4,5-PhAn, 1,12-TriP, 1,12-Per, 9,10-PhAn, 1,9-An, 1,10-PhAn, 2,3-PhAn, 1,2-PhAn, 1,10-Pyr, 1,2-Pyr, 2,3-Per, 3,4-FlAn, 2,3-FlAn, 1,2-FlAn, 3,4-Per, 7,8-FlAn, 8,9-FlAn, 2,3-TriP, 1,2-TriP, ace, or indeno substituent or their alkyl or aryl substituted derivative; or 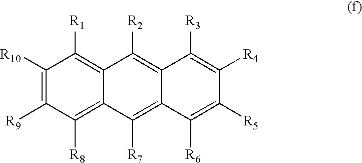
wherein:

substituents R₁ through R₁₀ are each individually hydrogen, fluoro, cyano, alkoxy, aryloxy, diarylamino, arylalkylamino, dialkylamino, trialkylsilyl, triarylsilyl, diarylalkylsilyl, dialkylarylsilyl, keto, dicyanomethyl, alkyl of from 1 to 24 carbon atoms, alkenyl of from 1 to 24 carbon atoms, alkynyl of from 1 to 24 carbon atoms, aryl of from 5 to 30 carbon atoms, substituted aryl, heterocycle containing at least one nitrogen atom, or at least one oxygen atom, or at least one sulfur atom, or at least one boron atom, or at least one phosphorus atom, or at least one silicon atom, or any combination thereof; or any two adjacent R₁ through R₁₀ substituents form an annelated benzo-, naphtho-, anthra-, phenanthro-, fluorantheno-, pyreno-, triphenyleno-, or peryleno-substituent or its alkyl or aryl substituted derivative; or any two R₁ through R₁₀ substituents form a 1,2-benzo, 1,2-naphtho, 2,3-naphtho, 1,8-naphtho, 1,2-anthraceno, 2,3-anthraceno, 2,2′-BP, 4,5-PhAn, 1,12-TriP, 1,12-Per, 9,10-PhAn, 1,9-An, 1,10-PhAn, 2,3-PhAn, 1,2-PhAn, 1,10-Pyr, 1,2-Pyr, 2,3-Per, 3,4-FlAn, 2,3-FlAn, 1,2-FlAn, 3,4-Per, 7,8-FlAn, 8,9-FlAn, 2,3-TriP, 1,2-TriP, ace, or indeno substituent or their alkyl or aryl substituted derivative; or 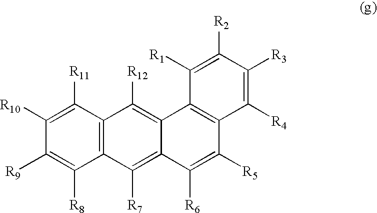
wherein:

substituents R₁ through R₁₂ are each individually hydrogen, fluoro, cyano, alkoxy, aryloxy, diarylamino, arylalkylamino, dialkylamino, trialkylsilyl, triarylsilyl, diarylalkylsilyl, dialkylarylsilyl, keto, dicyanomethyl, alkyl of from 1 to 24 carbon atoms, alkenyl of from 1 to 24 carbon atoms, alkynyl of from 1 to 24 carbon atoms, aryl of from 5 to 30 carbon atoms, substituted aryl, heterocycle containing at least one nitrogen atom, or at least one oxygen atom, or at least one sulfur atom, or at least one boron atom, or at least one phosphorus atom, or at least one silicon atom, or any combination thereof; or any two adjacent R₁ through R₁₂ substituents form an annelated benzo-, naphtho-, anthra-, phenanthro-, fluorantheno-, pyreno-, triphenyleno-, or peryleno-substituent or its alkyl or aryl substituted derivative; or any two R₁ through R₁₂ substituents form a 1,2-benzo, 1,2-naphtho, 2,3-naphtho, 1,8-naphtho, 1,2-anthraceno, 2,3-anthraceno, 2,2′-BP, 4,5-PhAn, 1,12-TriP, 1,12-Per, 9,10-PhAn, 1,9-An, 1,10-PhAn, 2,3-PhAn, 1,2-PhAn, 1,10-Pyr, 1,2-Pyr, 2,3-Per, 3,4-FlAn, 2,3-FlAn, 1,2-FlAn, 3,4-Per, 7,8-FlAn, 8,9-FlAn, 2,3-TriP, 1,2-TriP, ace, or indeno substituent or their alkyl or aryl substituted derivative.

One particular selection criterion for the first host component is that the organic compound should have a molecular structure that enables it to form an aggregate. The aggregate can be formed by at least two molecules of the same compound, such as the first host component, or by at least two molecules of two different compounds, such as the first and second host components or first component and the light-emitting dopant. All of these types of aggregates are useful in the present invention. However, the following discussion will be focused on the first case.

The term monomer of the first host component refers to the molecules of the first host component that do not interact with each other in either the ground or excited electronic state and thus they behave as individual molecules in a solid solution. In particular their absorption and emission processes are characteristic of an individual molecule. The absence of the interaction between the two individual molecules can be due to: e.g. the intrinsic lack of forces that enable the interaction, distances between the molecules being too large, improper geometry, steric hindrance, and other reasons.

An example of a material that does not form an aggregate is NPB. The solution absorption and emission spectra for NPB dissolved in ethyl acetate are shown in FIG. 5. The emission maximum was at 450 nm. The solution quantum yield was approximately 19%.

The thin film photoluminescence spectra and quantum yield for NPB was obtained by Mattoussi et al. in J. Appl. Phys., 86, 2642 (1999). They reported that with an NPB film thickness of 3100 Å, the absorption maximum was approximately 340 nm and the emission maximum was approximately 450 nm with a quantum yield of 41%. Comparing the solution data with the thin film data, it becomes evident that NPB does not form an aggregate. Alq is another example of a compound that does not form an aggregate, as can be inferred from the data provided by Naito et al. in Jpn. J. Appl. Phys. 38, 2792 (1999).

The aggregate is defined as a supra-molecular entity resulting from an interaction between two or more monomers. The interaction may be represented by van der Waals forces or charge-transfer interactions commonly known in the art. The aggregate has physical and chemical properties different from those of the monomer. In particular, two or more molecules can participate in cooperative absorption or emission or both, that is absorption or emission or both can only be understood as arising from molecular complexes or molecular aggregates formed from the interacting molecules. When two or more molecules act cooperatively to absorb a photon, it is said that the absorption aggregate exists in the ground electronic state. When two or more molecules act cooperatively to emit a photon, it is said that the exciplex, or a molecular complex or molecular aggregate, exists in the excited electronic state. The absorption aggregate need not form an exciplex upon excitation and the exciplex need not emit to produce a ground state aggregate. Thus, the aggregate can exist in either ground electronic state or excited electronic state or both. An aggregate can be only weakly associated in the ground electronic state (the energy of van der Waals interactions ˜1-3 kcal/mol) but more strongly associated in its excited electronic state (the energy of van der Waals interactions ˜3-10 kcal/mol). The simplest aggregate in the ground electronic state is often called a dimer, that is an aggregate formed by two molecules in their ground electronic states. The aggregate in the excited electronic state is called an excimer and in the simplest case is formed by two molecules, one of which prior to formation of the exciplex was in the ground electronic state and the other was in the excited electronic state. One of the most commonly observed features of aggregates is that their absorption spectrum or their emission spectrum are shifted compared to the absorption spectrum or emission spectrum of the monomers, respectively. It is possible for both absorption and emission spectra of an aggregate to be shifted relative to those of the monomer. The shift can occur to the red or to the blue. On the other hand, the absorption or emission spectra of aggregates can contain new features such as peaks and shoulders positioned to either red or blue compared to the absorption or emission spectrum of the monomers. Another commonly observed characteristic of aggregates is that the intensity and the position (wavelength) of the new or shifted absorption or emission depend on concentration of molecules that form the aggregate. With increasing concentration, the intensity of shifted absorption or emission features can increase due to the increasing concentration of the aggregates, while the position (wavelength) can shift too due to the increase in the size (number of molecules involved in the formation) of the aggregates. Another common characteristic of aggregates which is observed in the absence of readily detectable changes in the monomer absorption or emission spectrum is the change in the intensity (quantum yield of luminescence) of the monomer emission. For reference, these definitions can be found in N.J. Turro, Modern Molecular Photochemistry, University Science Books, Sausalito, Calif. 1991, p. 135, (section 5.12).

For some organic compounds, their molecular structure is such that their aggregates in excited electronic states are emissive, and thus can be readily observed by measuring fluorescence emission spectra as a function of concentration. Compounds that form emissive or highly emissive aggregates are potentially the most useful as first host components because they would effectively donate their electronic excitation energy to a properly chosen dopant. However, there are many organic compounds that form aggregates which are not emissive or only weakly emissive. Formation of essentially non-emissive aggregates (those with the quantum yield of luminescence of, e.g. from 0.001 to 0.1%) can lead to a decrease in the luminescence efficiency of the device due to insufficient electronic excitation energy transfer to the light-emitting dopant. Nevertheless, with certain types of compounds, especially the ones listed above, the quantum yield of luminescence of an aggregate is often found sufficient to cause efficient energy transfer from the excited state of the aggregate to the light-emitting dopant, according to the well known in the art Foerster energy transfer principle. Therefore, such compounds would provide high electroluminescence efficiency and are useful as first host components.

Another important criteria for selection of compounds as first host components is that the aggregate of these compounds should have spectroscopic characteristics, namely absorption and emission spectra, excited state lifetime, quantum yield of luminescence, and oscillator strength, such that efficient transfer of electronic excitation energy to the light-emitting dopant of appropriate color is insured.

Many of the benzenoid compounds found useful as the first host component in the present invention have a flat rigid geometry, which encourages formation of aggregates. Many representative benzenoids, such as pyrene, perylene, coronene, naphthacene, anthracene, pentacene, anthanthrene, picene, triphenylene, chrysene, fluoranthene, benzo[ghi]perylene, ovalene, and their mono- and poly-substituted benzo, naphtho, anthra, phenanthro, triphenyleno, and other derivatives have been shown in the common literature to possess a pronounced propensity for aggregate formation. The aggregates of these compounds are extensively characterized in common literature. If the PAH compound is emissive as a monomer, it is most often found to be emissive as an aggregate also, especially in the solid solutions (exactly as found in an OLED device). Other organic compounds meeting such a planar geometry criteria are useful as well.

Although aggregates including two molecules are most often found and described in the literature, often it is found that compounds such as disclosed in the present invention are capable of forming aggregates including more than two molecules as the volume % increases.

Materials for the second host component of the light-emitting layer of the present invention include organic compounds that are capable of transporting electrical charges and are capable of forming a continuous and substantially pin-hole-free thin film upon mixing with the first host component. They can be polar, such as (i) the common host for green, yellow, orange, and red OLEDs, Alq₃, and other oxinoid and oxinoid-like materials and metal complexes, and (ii) common hosts from the heterocyclic family for blue, blue-green, green, yellow, orange, and red OLEDs such as those based on oxadiazole, imidazole, pyridine, phenanthroline, triazine, triazole, quinoline and other moieties. They also can be nonpolar, such as (i) the common hosts from the anthracene family for blue, blue-green, green, yellow, orange, and red OLEDs, such as 2-(1,1-dimethylethyl)-9,10-bis(2-naphthalenyl)anthracene (TBADN), 9,10-Bis[4-(2,2-diphenylethenyl)phenyl]anthracene, and 10,10′-Diphenyl-9,9′-bianthracene; (ii) common hosts of rubrene family for yellow, orange, and red OLEDs, such as rubrene and 5,6,11,12-tetrakis(2-naphthyl)tetracene; and (iii) common hosts of triarylamine family for blue, blue-green, green, yellow, orange, and red OLEDs such as NPB, TNB, and TPD. The second host component can have a bandgap that is less than, more than, or equal to that of the first host component as either a monomer or aggregate. The bandgap (or energy gap) is defined as the energy needed to bring an electron from the highest occupied molecular orbital to the lowest unoccupied molecular orbital of the molecule. When the bandgap of the first host component as a monomer is approximately equal to that of the second host component and the dopant is absent, the photoluminescence (PL) and electroluminescence (EL) spectra are composed of the emission spectra of both species. When the bandgap of the first host component as a monomer is approximately equal to that of the first host component as an aggregate and to that of the second host component (while the dopant is absent), the PL and EL spectra are composed of the emission spectra of all three species. When the bandgap of the first host component as an aggregate is smaller than that of the second host component and the dopant is absent, the PL and EL spectra are dominated by the emission spectrum of the first host component as an aggregate.

The necessary condition is that the bandgap of the light-emitting dopant be smaller than: a) the bandgap of the second host component; b) the bandgap of first host component as a monomer; and c) the bandgap of the first host component as an aggregate. This ensures that electronic excitation energy transfer from the first and second host components, resulting from the recombination of electrons and holes in the first and second host components, to the light-producing dopants is favorable.

Among the second host component, the first host component as a monomer, and the first host component as an aggregate, the material that has the lowest bandgap would likely serve as a trap for holes, or electrons, or both. Trapping charge carriers by the first host component can be beneficial as it promotes electron-hole recombination in this host component, shortcutting the need for carrier recombination in the second host component. Under this condition, the second host component is needed for carrier transport at most and not for charge carrier recombination, which could lead to electroluminescence degradation.

The first preferred class of materials for the second host component is the oxinoid compounds. As described previously, exemplary of contemplated oxinoid compounds are those satisfying the following structural formula: 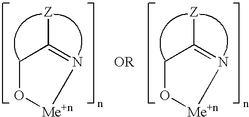
wherein:
Me represents a metal;
n is an integer of from 1 to 3; and
Z independently in each occurrence represents the atoms completing a nucleus having at least two fused aromatic rings.

From the foregoing it is apparent that the metal can be monovalent, divalent, or trivalent metal. The metal can, for example, be an alkali metal, such as lithium, sodium, rubidium, cesium, or potassium; an alkaline earth metal, such as magnesium, beryllium, strontium, barium, or calcium; or an earth metal, such as boron or aluminum, gallium, and indium. Generally any monovalent, divalent, or trivalent metal known to be a useful chelating metal can be employed.

Z completes a heterocyclic nucleus containing at least two fused aromatic rings, at least one of which is an azole or azine ring. Additional rings, including both aliphatic and aromatic rings, can be fused with the two required rings, if required. To avoid adding molecular bulk without improving on function the number of ring atoms is preferably maintained at 18 or less.

Illustrative of useful chelated oxinoid compounds and their abbreviated names are the following:
Tris(8-quinolinol)aluminum (Alq₃);
Bis(8-quinolinol)magnesium (MgQ₂);
Tris(8-quinolinol)gallium (GaQ₃); or
8-quinolinol lithium (LiQ).
   The list further includes InQ₃, ScQ₃, ZnQ₂, BeBq₂ (bis(10-hydroxybenzo-[h]quinolinato)beryllium), Al(4-MeQ)₃, Al(2-MeQ)₃, Al(2,4-Me₂Q)₃, Ga(4-MeQ)₃, Ga(2-MeQ)₃, Ga(2,4-Me₂Q)₃, and Mg(2-MeQ)₂. The list of oxinoid compounds further includes metal complexes with two bi-dentate ligands and one mono-dentate ligand, for example Al(2-MeQ)₂(X) where X is any aryloxy, alkoxy, arylcaboxylate, and heterocyclic carboxylate group.

Another class of materials useful as the second host component includes structures having an anthracene moiety. Exemplary of contemplated anthracene compounds are those satisfying the following structural formula: 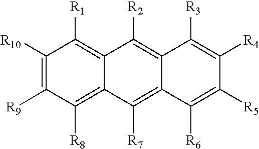
wherein

substituents R₂ and R₇ are each individually and independently alkenyl of from 1 to 24 carbon atoms, alkynyl of from 1 to 24 carbon atoms, aryl of from 5 to 30 carbon atoms, substituted aryl, heterocycle containing at least one nitrogen atom, or at least one oxygen atom, or at least one sulfur atom, or at least one boron atom, or at least one phosphorus atom, or at least one silicon atom, or any combination thereof; and substituents R₁ through R₁₀ excluding R₂ and R₇ are each individually hydrogen, fluoro, cyano, alkoxy, aryloxy, diarylamino, arylalkylamino, dialkylamino, trialkylsilyl, triarylsilyl, diarylalkylsilyl, dialkylarylsilyl, keto, dicyanomethyl, alkyl of from 1 to 24 carbon atoms, alkenyl of from 1 to 24 carbon atoms, alkynyl of from 1 to 24 carbon atoms, aryl of from 5 to 30 carbon atoms, substituted aryl, heterocycle containing at least one nitrogen atom, or at least one oxygen atom, or at least one sulfur atom, or at least one boron atom, or at least one phosphorus atom, or at least one silicon atom, or any combination thereof; or any two adjacent R₁ through R₁₀ substituents excluding R₂ and R₇ form an annelated benzo-, naphtho-, anthra-, phenanthro-, fluorantheno-, pyreno-, triphenyleno-, or peryleno-substituent or its alkyl or aryl substituted derivative; or any two adjacent R₁ through R₁₀ substituents excluding R₂ and R₇ form a 1,2-benzo, 1,2-naphtho, 2,3-naphtho, 1,8-naphtho, 1,2-anthraceno, 2,3-anthraceno, 2,2′-BP, 4,5-PhAn, 1,12-TriP, 1,12-Per, 9,10-PhAn, 1,9-An, 1,10-PhAn, 2,3-PhAn, 1,2-PhAn, 1,10-Pyr, 1,2-Pyr, 2,3-Per, 3,4-FlAn, 2,3-FlAn, 1,2-FlAn, 3,4-Per, 7,8-FlAn, 8,9-FlAn, 2,3-TriP, 1,2-TriP, ace, or indeno substituent or their alkyl or aryl substituted derivative.

Illustrative of useful anthracene compounds and their abbreviated names are the following:
2-(1,1-dimethylethyl)-9,10-bis(2-naphthalenyl)anthracene (TBADN);
9,10-bis(2-naphthalenyl)anthracene (ADN);
9,10-bis(1-naphthalenyl)anthracene;
9,10-Bis[4-(2,2-diphenylethenyl)phenyl]anthracene;
9,10-Bis([1,1′:3′,1″-terphenyl]-5′-yl)anthracene;
9,9′-Bianthracene;
10,10′-Diphenyl-9,9′-bianthracene;
10,10′-Bis([1,1′:3′,1″-terphenyl]-5′-yl)-9,9′-bianthracene;
2,2′-Bianthracene;
9,9′, 10,10′-Tetraphenyl-2,2′-bianthracene;
9,10-Bis(2-phenylethenyl)anthracene; or
9-Phenyl-10-(phenyl ethynyl)anthracene.

Another class of materials useful as the second host component includes structures having an amine moiety. Exemplary of contemplated amino compounds are those satisfying the following structural formula: 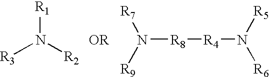
wherein:

substituents R₄ and R₈ are each individually and independently aryl, or substituted aryl of from 5 to 30 carbon atoms, heterocycle containing at least one nitrogen atom, or at least one oxygen atom, or at least one sulfur atom, or at least one boron atom, or at least one phosphorus atom, or at least one silicon atom, or any combination thereof; substituents R₄ and R₈ each or together (“R₄-R₈”) representing an aryl group such as benzene, naphthalene, anthracene, tetracene, pyrene, perylene, chrysene, phenathrene, triphenylene, tetraphene, coronene, fluoranthene, pentaphene, ovalene, picene, anthanthrene and their homologs and also their 1,2-benzo, 1,2-naphtho, 2,3-naphtho, 1,8-naphtho, 1,2-anthraceno, 2,3-anthraceno, 2,2′-BP, 4,5-PhAn, 1,12-TriP, 1,12-Per, 9,10-PhAn, 1,9-An, 1,10-PhAn, 2,3-PhAn, 1,2-PhAn, 1,10-Pyr, 1,2-Pyr, 2,3-Per, 3,4-FlAn, 2,3-FlAn, 1,2-FlAn, 3,4-Per, 7,8-FlAn, 8,9-FlAn, 2,3-TriP, 1,2-TriP, ace, or indeno substituted derivatives; and substituents R₁ through R₉ excluding R₄ and R₈ are each individually hydrogen, silyl, alkyl of from 1 to 24 carbon atoms, aryl of from 5 to 30 carbon atoms, substituted aryl, heterocycle containing at least one nitrogen atom, or at least one oxygen atom, or at least one sulfur atom, or at least one boron atom, or at least one phosphorus atom, of at least one silicon atom, or any combination thereof.

Illustrative of useful amino compounds and their abbreviated names are the following:
N,N′-bis(1-naphthalenyl)-N,N′-diphenylbenzidine (NPB);
N,N′-bis(1-naphthalenyl)-N,N′-bis(2-naphthalenyl)benzidine (TNB);
N,N′-bis(3-methylphenyl)-N,N′-diphenylbenzidine (TPD); or
N,N′-Bis(N″,N″-diphenylaminonaphthalen-5-yl)-N,N′-diphenyl-1,5-diaminonaphthalene (CAS 503624-47-3).

Another class of materials useful as the second host component includes structures having a fluorene moiety. Exemplary of contemplated fluorene compounds are those satisfying the following structural formula: 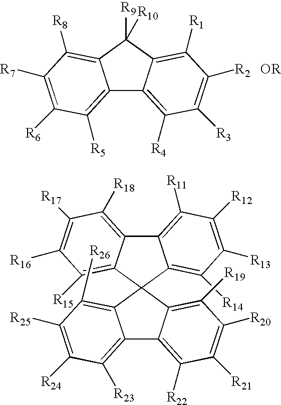
wherein:

substituents R₁ through R₂₅ are each individually hydrogen, fluoro, cyano, alkoxy, aryloxy, diarylamino, arylalkylamino, dialkylamino, trialkylsilyl, triarylsilyl, diarylalkylsilyl, dialkylarylsilyl, keto, dicyanomethyl, alkyl of from 1 to 24 carbon atoms, alkenyl of from 1 to 24 carbon atoms, alkynyl of from 1 to 24 carbon atoms, aryl of from 5 to 30 carbon atoms, substituted aryl, heterocycle containing at least one nitrogen atom, or at least one oxygen atom, or at least one sulfur atom, or at least one boron atom, or at least one phosphorus atom, or at least one silicon atom, or any combination thereof; or any two adjacent R₁ through R₂₅ substituents excluding R₉ and R₁₀ form an annelated benzo-, naphtho-, anthra-, phenanthro-, fluorantheno-, pyreno-, triphenyleno-, or peryleno-substituent or its alkyl or aryl substituted derivative; or any two R₁ through R₂₅ substituents excluding R₉ and R₁₀ form a 1,2-benzo, 1,2-naphtho, 2,3-naphtho, 1,8-naphtho, 1,2-anthraceno, 2,3-anthraceno, 2,2′-BP, 4,5-PhAn, 1,12-TriP, 1,12-Per, 9,10-PhAn, 1,9-An, 1,10-PhAn, 2,3-PhAn, 1,2-PhAn, 1,10-Pyr, 1,2-Pyr, 2,3-Per, 3,4-FlAn, 2,3-FlAn, 1,2-FlAn, 3,4-Per, 7,8-FlAn, 8,9-FlAn, 2,3-TriP, 1,2-TriP, ace, or indeno substituent or their alkyl or aryl substituted derivative.

Illustrative of useful fluorene compounds and their abbreviated names are the following:
2,2′,7,7′-Tetraphenyl-9,9′-spirobi[9H-fluorene];
2,2′,7,7′-Tetra-2-phenanthrenyl-9,9′-spirobi[9H-fluorene];
2,2′-Bis (4-N,N-diphenyl aminophenyl)-9,9′-spirobi[9H-fluorene] (CAS 503307-40-2);
4′-Phenyl-spiro[fluorene-9,6′-[6H]indeno[1,2-j]fluoranthene];
2,3,4-Triphenyl-9,9′-spirobifluorene;
11,11′-Spirobi[11H-benzo[b]fluorene];
9,9′-Spirobi[9H-fluorene]-2,2′-diamine;
9,9′-Spirobi[9H-fluorene]-2,2′-dicarbonitrile;
2′,7′-Bis([1,1′-biphenyl]-4-yl)-N,N,N′,N′-tetraphenyl-9,9′-spirobi[9H-fluorene]-2,7-diamine;
9,9,9′,9′,9″,9″-Hexaphenyl-2,2′:7′,2″-ter-9H-fluorene;
2,7-Bis([1,1′-biphenyl]-4-yl)-9,9′-spirobi[9H-fluorene];
2,2′,7,7′-tetra-2-Naphthalenyl-9,9′-spirobi[9H-fluorene]; or
9,9′-[(2,7-Diphenyl-9H-fluoren-9-ylidene)di-4,1-phenylene]bis-anthracene.

Another class of materials useful as the second host component includes structures having a naphthacene moiety. Exemplary of contemplated naphthacene compounds are those satisfying the following structural formula: 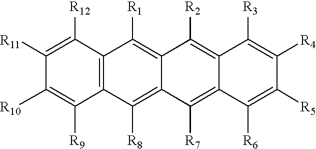
wherein:

substituents R₁ through R₁₂ are each individually hydrogen, fluoro, cyano, alkoxy, aryloxy, diarylamino, arylalkylamino, dialkylamino, trialkylsilyl, triarylsilyl, diarylalkylsilyl, dialkylarylsilyl, keto, dicyanomethyl, alkyl of from 1 to 24 carbon atoms, alkenyl of from 1 to 24 carbon atoms, alkynyl of from 1 to 24 carbon atoms, aryl of from 5 to 30 carbon atoms, substituted aryl, heterocycle containing at least one nitrogen atom, or at least one oxygen atom, or at least one sulfur atom, or at least one boron atom, or at least one phosphorus atom, or at least one silicon atom, or any combination thereof, or any two adjacent R₁ through R₁₂ substituents form an annelated benzo-, naphtho-, anthra-, phenanthro-, fluorantheno-, pyreno-, triphenyleno-, or peryleno-substituent or its alkyl or aryl substituted derivative; or any two R₁ through R₁₂ substituents form a 1,2-benzo, 1,2-naphtho, 2,3-naphtho, 1,8-naphtho, 1,2-anthraceno, 2,3-anthraceno, 2,2′-BP, 4,5-PhAn, 1,12-TriP, 1,12-Per, 9,10-PhAn, 1,9-An, 1,10-PhAn, 2,3-PhAn, 1,2-PhAn, 1,10-Pyr, 1,2-Pyr, 2,3-Per, 3,4-FlAn, 2,3-FlAn, 1,2-FlAn, 3,4-Per, 7,8-FlAn, 8,9-FlAn, 2,3-TriP, 1,2-TriP, ace, or indeno substituent or their alkyl or aryl substituted derivative.

Illustrative of useful naphthacene compounds and their abbreviated names are the following:
5,6,11,12-Tetraphenylnaphthacene (rubrene);
5,12-Bis(2-naphthyl)-6,11-diphenyltetracene;
5,12-Bis(2-mesityl)-6,11-diphenyltetracene;
5,12-Bis(1-naphthyl)-6,11-diphenyltetracene;
5,6,11,12-Tetrakis(2-naphthyl)tetracene;
10,10′-[(6,11-Diphenyl-5,12-naphthacenediyl)di-4,1-phenylene]bis[2,3,6,7-tetrahydro-1H,5H-benzothiazolo[5,6,7-ij]quinolizine;
9,10,15,16-Tetraphenyl-dibenzo[a,c]naphthacene;
5,6,13,14-Tetraphenylpentacene;
4,4′-(8,9-Dimethyl-5,6,7,10,11,12-hexaphenyl-1,4-naphthacenediyl)bis-benzonitrile;
4,4′-(8,9-Dimethoxy-5,6,7,10,11,12-hexaphenyl-1,4-naphthacenediyl)bis[N,N-diphenylbenzenamine];
1,2,3,5,6,11,12-Heptaphenylnaphthacene;
1,4,5,6,7,10,11,12-Octaphenylnaphthacene;
6,11-diphenyl-5,12-bis(4′-N,N-diphenylaminophenyl)naphthacene;
7,8,15,16-Tetraphenyl-benzo[a]pentacene;
2,3,5,6,11,12-Hexaphenylnaphthacene;
6,11-diphenyl-5,12-bis(4′-cyanophenyl)naphthacene;
6,11-diphenyl-5,12-bis(4′-(2-thienyl)phenyl)naphthacene; or
9,10,19,20-Tetraphenyl-tetrabenzo[a,c,j,l]naphthacene.

Another class of materials useful as the second host component includes benzenoids that contain other heterocyclic structures. These structures include benzoxazolyl, and thio and amino analogs of benzoxazolyl of following general molecular structure: 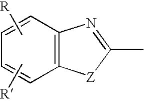
wherein:

Z is O, NR″ or S;

R and R′, are individually hydrogen, alkyl of from 1 to 24 carbon atoms, aryl or hetero-atom substituted aryl of from 5 to 20 carbon atoms, fluoro, cyano, alkoxy, aryloxy, diarylamino, arylalkylamino, dialkylamino, trialkylsilyl, triarylsilyl, diarylalkylsilyl, dialkylarylsilyl, keto, dicyanomethyl, alkyl of from 1 to 24 carbon atoms, alkenyl of from 1 to 24 carbon atoms, alkynyl of from 1 to 24 carbon atoms, aryl of from 5 to 30 carbon atoms, substituted aryl, heterocycle containing at least one nitrogen atom, or at least one oxygen atom, or at least one sulfur atom, or at least one boron atom, or at least one phosphorus atom, or at least one silicon atom, or any combination thereof; or atoms necessary to complete a fused aromatic ring; and

R″ is hydrogen; alkyl of from 1 to 24 carbon atoms; or aryl of from 5 to 20 carbon atoms.

These structures further include alkyl, alkenyl, alkynyl, aryl, substituted aryl, benzo-, naphtho-, anthra-, phenanthro-, fluorantheno-, pyreno-, triphenyleno-, or peryleno-, 1,2-benzo, 1,2-naphtho, 2,3-naphtho, 1,8-naphtho, 1,2-anthraceno, 2,3-anthraceno, 2,2′-BP, 4,5-PhAn, 1,12-TriP, 1,12-Per, 9,10-PhAn, 1,9-An, 1,10-PhAn, 2,3-PhAn, 1,2-PhAn, 1,10-Pyr, 1,2-Pyr, 2,3-Per, 3,4-FlAn, 2,3-FlAn, 1,2-FlAn, 3,4-Per, 7,8-FlAn, 8,9-FlAn, 2,3-TriP, 1,2-TriP, ace, indeno, fluoro, cyano, alkoxy, aryloxy, amino, aza, heterocyclic, keto, or dicyanomethyl derivatives thereof.

The material selection criteria for the dopant in the light-emitting layer are: 1) the dopant molecule has a high efficiency of fluorescence or phosphorescence in the light-emitting layer, and 2) it has a bandgap (singlet bandgap for the case of fluorescent dopants and triplet bandgap for the case of phosphorescent dopants) smaller than that of the both first and second host materials, the first component being either a monomer or an aggregate.

For red-emitting OLEDs, a preferred class of dopants of this invention is the DCM class and has the general formula: 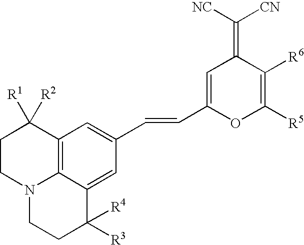
wherein:

R¹, R², R³, and R⁴ are individually alkyl of from 1 to 10 carbon atoms; R⁵ is alkyl of from 2 to 20 carbon atoms, aryl, sterically hindered aryl, or heteroaryl; and R⁶ is alkyl of from 1 to 10 carbon atoms, or a 5- or 6-membered carbocyclic, aromatic, or heterocyclic ring connecting with R⁵.

These materials possess fluorescence efficiencies as high as unity in solutions and emit in the orange and red spectral region. Representative materials of this class and their abbreviated names include:

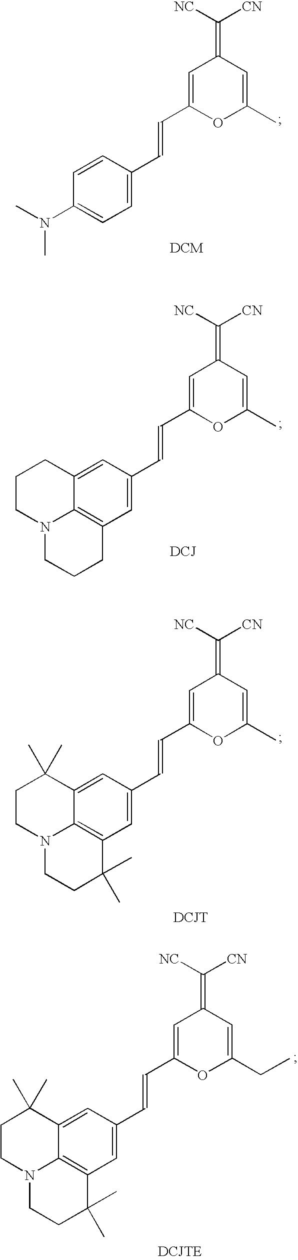

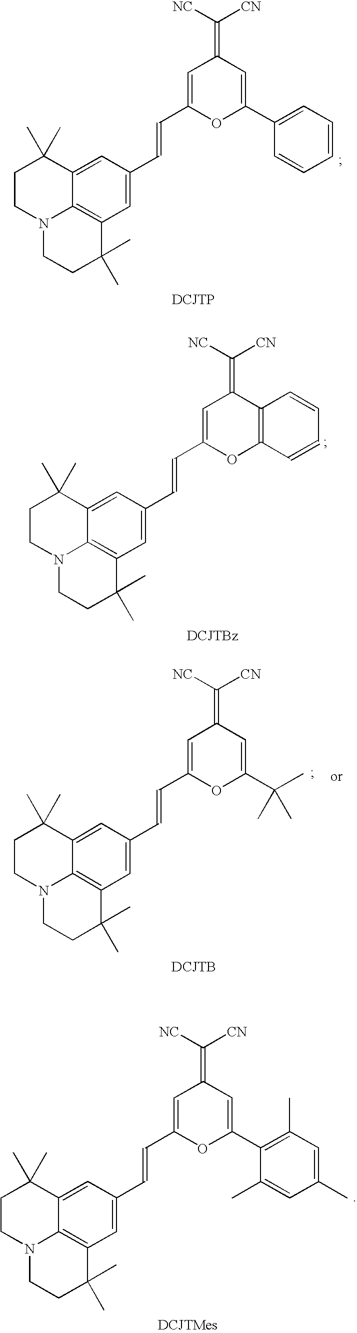

For red-emitting OLEDs, another preferred class of dopants of this invention comprises compounds having a periflanthene moiety 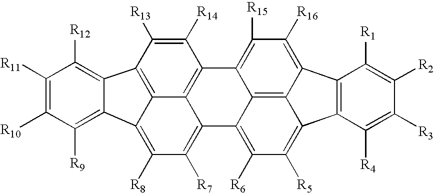
wherein:

substituents R₁ through R₁₆ are each individually hydrogen, fluoro, cyano, alkoxy, aryloxy, diarylamino, arylalkylamino, dialkylamino, trialkylsilyl, triarylsilyl, diarylalkylsilyl, dialkylarylsilyl, keto, dicyanomethyl, alkyl of from 1 to 24 carbon atoms, alkenyl of from 1 to 24 carbon atoms, alkynyl of from 1 to 24 carbon atoms, aryl of from 5 to 30 carbon atoms, substituted aryl, heterocycle containing at least one nitrogen atom, or at least one oxygen atom, or at least one sulfur atom, or at least one boron atom, or at least one phosphorus atom, or at least one silicon atom, or any combination thereof; or any two adjacent R₁ through R₁₆ substituents form an annelated benzo-, naphtho-, anthra-, phenanthro-, fluorantheno-, pyreno-, triphenyleno-, or peryleno-substituent or its alkyl or aryl substituted derivative; or any two R₁ through R₁₆ substituents form a 1,2-benzo, 1,2-naphtho, 2,3-naphtho, 1,8-naphtho, 1,2-anthraceno, 2,3-anthraceno, 2,2′-BP, 4,5-PhAn, 1,12-TriP, 1,12-Per, 9,10-PhAn, 1,9-An, 1,10-PhAn, 2,3-PhAn, 1,2-PhAn, 1,10-Pyr, 1,2-Pyr, 2,3-Per, 3,4-FlAn, 2,3-FlAn, 1,2-FlAn, 3,4-Per, 7,8-FlAn, 8,9-FlAn, 2,3-TriP, 1,2-TriP, ace, or indeno substituent or their alkyl or aryl substituted derivative.

These materials possess fluorescence efficiencies as high as unity in solutions and emit in the orange and red spectral region. One representative material of this class is

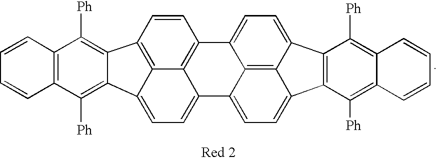

For green-emitting OLEDs, a class of fluorescent materials is useful as the dopants in the present invention, which includes compounds having a coumarin moiety 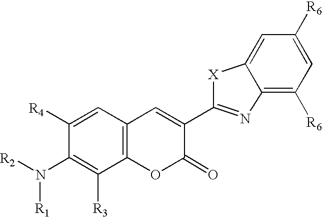
wherein:

X=S, O, or NR₇; R₁ and R₂ are individually alkyl of from 1 to 20 carbon atoms, aryl or carbocyclic systems; R₃ and R₄ are individually alkyl of from 1 to 10 carbon atoms, or a branched or unbranched 5 or 6 member substituent ring connecting with R₁ and R₂, respectively; R₅ and R₆ are individually alkyl of from 1 to 20 carbon atoms, which are branched or unbranched; and R₇ is any alkyl or aryl group.

These materials possess fluorescence efficiencies as high as unity in solutions. Representative materials of this class and their abbreviated names include

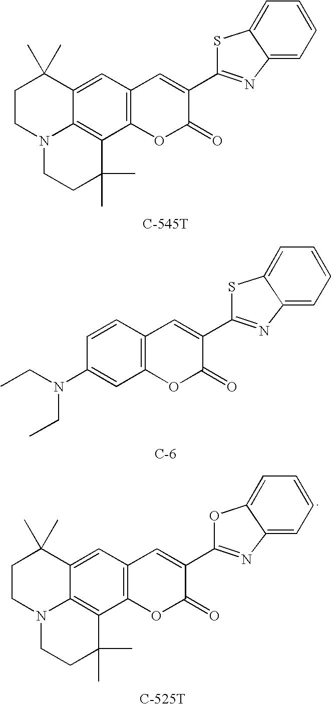

For green-emitting OLEDs, another class of fluorescent materials is useful as the dopants in the present invention, which includes compounds having a quinacridone moiety 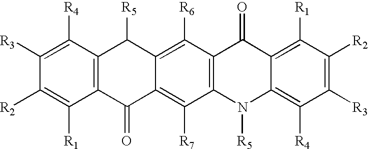
wherein:

substituents R₁ through R₇ are each individually hydrogen, fluoro, cyano, alkoxy, aryloxy, diarylamino, arylalkylamino, dialkylamino, trialkylsilyl, triarylsilyl, diarylalkylsilyl, dialkylarylsilyl, keto, dicyanomethyl, alkyl of from 1 to 24 carbon atoms, alkenyl of from 1 to 24 carbon atoms, alkynyl of from 1 to 24 carbon atoms, aryl of from 5 to 30 carbon atoms, substituted aryl, heterocycle containing at least one nitrogen atom, or at least one oxygen atom, or at least one sulfur atom, or at least one boron atom, or at least one phosphorus atom, or at least one silicon atom, or any combination thereof; or any two adjacent R₁ through R₄ substituents form an annelated benzo-, naphtho-, anthra-, phenanthro-, fluorantheno-, pyreno-, triphenyleno-, or peryleno-substituent or its alkyl or aryl substituted derivative; or any two R₁ through R⁴ substituents form a 1,2-benzo, 1,2-naphtho, 2,3-naphtho, 1,8-naphtho, 1,2-anthraceno, 2,3-anthraceno, 2,2′-BP, 4,5-PhAn, 1,12-TriP, 1,12-Per, 9,10-PhAn, 1,9-An, 1,10-PhAn, 2,3-PhAn, 1,2-PhAn, 1,10-Pyr, 1,2-Pyr, 2,3-Per, 3,4-FlAn, 2,3-FlAn, 1,2-FlAn, 3,4-Per, 7,8-FlAn, 8,9-FlAn, 2,3-TriP, 1,2-TriP, ace, or indeno substituent or their alkyl or aryl substituted derivative.

These materials possess fluorescence efficiencies as high as unity in solutions. Representative materials of this class and their abbreviated names include

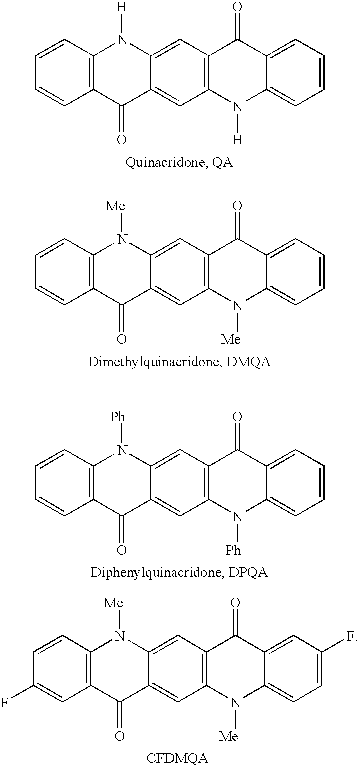

For green, green-yellow, and yellow emitting OLEDs, another class of fluorescent materials is useful as the dopants in the present invention, which includes compounds having a DPMB (dipyridinomethene borate) moiety 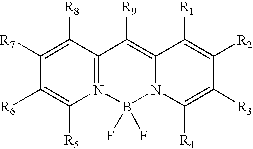
wherein:

substituents R¹ through R⁹ are each individually hydrogen, fluoro, cyano, alkoxy, aryloxy, diarylamino, arylalkylamino, dialkylamino, trialkylsilyl, triarylsilyl, diarylalkylsilyl, dialkylarylsilyl, keto, dicyanomethyl, alkyl of from 1 to 24 carbon atoms, alkenyl of from 1 to 24 carbon atoms, alkynyl of from 1 to 24 carbon atoms, aryl of from 5 to 30 carbon atoms, substituted aryl, heterocycle containing at least one nitrogen atom, or at least one oxygen atom, or at least one sulfur atom, or at least one boron atom, or at least one phosphorus atom, or at least one silicon atom, or any combination thereof; or any two adjacent R₁ through R₉ substituents form an annelated benzo-, naphtho-, anthra-, phenanthro-, fluorantheno-, pyreno-, triphenyleno-, or peryleno-substituent or its alkyl or aryl substituted derivative; or any two R₁ through R₉ substituents form a 1,2-benzo, 1,2-naphtho, 2,3-naphtho, 1,8-naphtho, 1,2-anthraceno, 2,3-anthraceno, 2,2′-BP, 4,5-PhAn, 1,12-TriP, 1,12-Per, 9,10-PhAn, 1,9-An, 1,10-PhAn, 2,3-PhAn, 1,2-PhAn, 1,10-Pyr, 1,2-Pyr, 2,3-Per, 3,4-FlAn, 2,3-FlAn, 1,2-FlAn, 3,4-Per, 7,8-FlAn, 8,9-FlAn, 2,3-TriP, 1,2-TriP, ace, or indeno substituent or their alkyl or aryl substituted derivative.

These materials possess fluorescence efficiencies as high as unity in solutions. Representative materials of this class include:

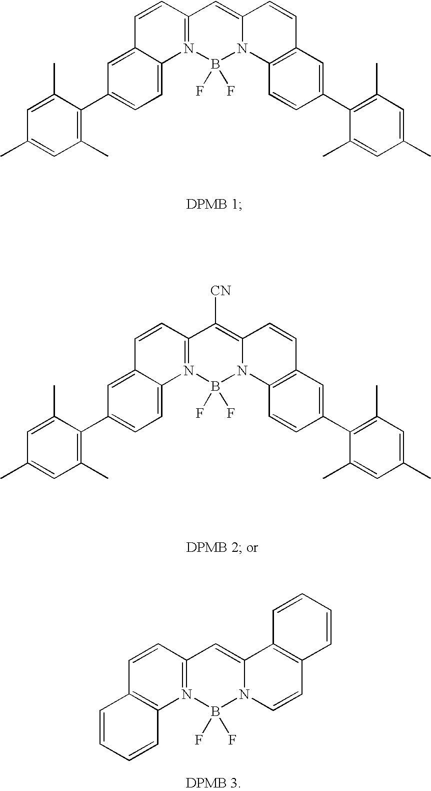

For yellow- and orange-emitting OLEDs, a preferred class of dopants for this invention includes compounds having an indenoperylene moiety 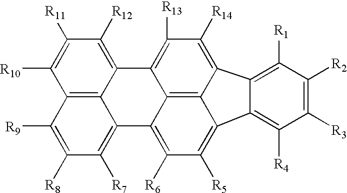
wherein:

substituents R₁ through R₁₄ are each individually hydrogen, fluoro, cyano, alkoxy, aryloxy, diarylamino, arylalkylamino, dialkylamino, trialkylsilyl, triarylsilyl, diarylalkylsilyl, dialkylarylsilyl, keto, dicyanomethyl, alkyl of from 1 to 24 carbon atoms, alkenyl of from 1 to 24 carbon atoms, alkynyl of from 1 to 24 carbon atoms, aryl of from 5 to 30 carbon atoms, substituted aryl, heterocycle containing at least one nitrogen atom, or at least one oxygen atom, or at least one sulfur atom, or at least one boron atom, or at least one phosphorus atom, or at least one silicon atom, or any combination thereof; or any two adjacent R₁ through R₁₄ substituents form an annelated benzo-, naphtho-, anthra-, phenanthro-, fluorantheno-, pyreno-, triphenyleno-, or peryleno-substituent or its alkyl or aryl substituted derivative; or any two R₁ through R₁₄ substituents form a 1,2-benzo, 1,2-naphtho, 2,3-naphtho, 1,8-naphtho, 1,2-anthraceno, 2,3-anthraceno, 2,2′-BP, 4,5-PhAn, 1,12-TriP, 1,12-Per, 9,10-PhAn, 1,9-An, 1,10-PhAn, 2,3-PhAn, 1,2-PhAn, 1,10-Pyr, 1,2-Pyr, 2,3-Per, 3,4-FlAn, 2,3-FlAn, 1,2-FlAn, 3,4-Per, 7,8-FlAn, 8,9-FlAn, 2,3-TriP, 1,2-TriP, ace, or indeno substituent or their alkyl or aryl substituted derivative.

These materials possess fluorescence efficiencies as high as unity in solutions. One representative material of this class is

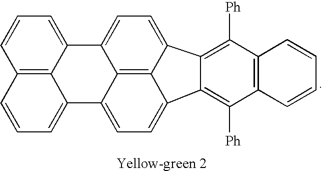

For yellow- and orange-emitting OLEDs, another preferred class of dopants for this invention includes compounds having a naphthacene moiety 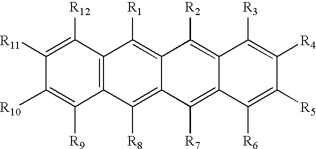
wherein:

substituents R₁ through R₁₂ are each individually hydrogen, fluoro, cyano, alkoxy, aryloxy, diarylamino, arylalkylamino, dialkylamino, trialkylsilyl, triarylsilyl, diarylalkylsilyl, dialkylarylsilyl, keto, dicyanomethyl, alkyl of from 1 to 24 carbon atoms, alkenyl of from 1 to 24 carbon atoms, alkynyl of from 1 to 24 carbon atoms, aryl of from 5 to 30 carbon atoms, substituted aryl, heterocycle containing at least one nitrogen atom, or at least one oxygen atom, or at least one sulfur atom, or at least one boron atom, or at least one phosphorus atom, or at least one silicon atom, or any combination thereof; or any two adjacent R₁ through R₁₂ substituents form an annelated benzo-, naphtho-, anthra-, phenanthro-, fluorantheno-, pyreno-, triphenyleno-, or peryleno-substituent or its alkyl or aryl substituted derivative; or any two R₁ through R₁₂ substituents form a 1,2-benzo, 1,2-naphtho, 2,3-naphtho, 1,8-naphtho, 1,2-anthraceno, 2,3-anthraceno, 2,2′-BP, 4,5-PhAn, 1,12-TriP, 1,12-Per, 9,10-PhAn, 1,9-An, 1,10-PhAn, 2,3-PhAn, 1,2-PhAn, 1,10-Pyr, 1,2-Pyr, 2,3-Per, 3,4-FlAn, 2,3-FlAn, 1,2-FlAn, 3,4-Per, 7,8-FlAn, 8,9-FlAn, 2,3-TriP, 1,2-TriP, ace, or indeno substituent or their alkyl or aryl substituted derivative.

These materials possess fluorescence efficiencies as high as unity in solutions and emit in the spectral region from greenish-yellow to red. Representative materials of this class and their abbreviated names include:
5,6,11,12-Tetraphenylnaphthacene (rubrene);
2,2′-[(6,11-diphenyl-5,12-naphthacenediyl)di-4,1-phenylene]bis(6-methylbenzothiazole) (Orange 2);
5,12-Bis(2-mesityl)-6,11-diphenyltetracene;
5,6,11,12-Tetrakis(2-naphthyl)tetracene;
10,10′-[(6,11-Diphenyl-5,12-naphthacenediyl)di-4,1-phenylene]-bis[2,3,6,7-tetrahydro-1H,5H-benzothiazolo[5,6,7-ij]quinolizine;
5,6,13,14-Tetraphenylpentacene;
4,4′-(8,9-Dimethoxy-5,6,7,10,11,12-hexaphenyl-1,4-naphthacenediyl)-bis[N,N-diphenylbenzenamine];
6,11-diphenyl-5,12-bis(4′-N,N-diphenylaminophenyl)naphthacene;
7,8,15,16-Tetraphenyl-benzo[a]pentacene; or
6,11-diphenyl-5,12-bis(4′-cyanophenyl)naphthacene.

For green-blue, blue-green, and blue-emitting OLEDs, a preferred class of dopants for this invention includes compounds having a BASB (bisaminostyrylbenzene) moiety 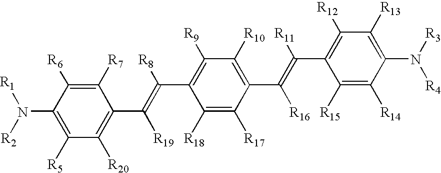
wherein:

each double bond can be either E or Z independently of the other double bond; substituents R₁ through R₄ are each individually and independently alkyl of from 1 to 24 carbon atoms, aryl, or substituted aryl of from 5 to 30 carbon atoms, heterocycle containing at least one nitrogen atom, or at least one oxygen atom, or at least one sulfur atom, or at least one boron atom, or at least one phosphorus atom, or at least one silicon atom, or any combination thereof; and substituents R₅ through R₂₀ are each individually hydrogen, fluoro, cyano, alkoxy, aryloxy, diarylamino, arylalkylamino, dialkylamino, trialkylsilyl, triarylsilyl, diarylalkylsilyl, dialkylarylsilyl, keto, dicyanomethyl, alkyl of from 1 to 24 carbon atoms, alkenyl of from 1 to 24 carbon atoms, alkynyl of from 1 to 24 carbon atoms, aryl of from 5 to 30 carbon atoms, substituted aryl, heterocycle containing at least one nitrogen atom, or at least one oxygen atom, or at least one sulfur atom, or at least one boron atom, or at least one phosphorus atom, or at least one silicon atom, or any combination thereof; or any two adjacent R₅ through R₂₀ substituents form an annelated benzo-, naphtho-, anthra-, phenanthro-, fluorantheno-, pyreno-, triphenyleno-, or peryleno-substituent or its alkyl or aryl substituted derivative; or any two R₅ through R₂₀ substituents form a 1,2-benzo, 1,2-naphtho, 2,3-naphtho, 1,8-naphtho, 1,2-anthraceno, 2,3-anthraceno, 2,2′-BP, 4,5-PhAn, 1,12-TriP, 1,12-Per, 9,10-PhAn, 1,9-An, 1,10-PhAn, 2,3-PhAn, 1,2-PhAn, 1,10-Pyr, 1,2-Pyr, 2,3-Per, 3,4-FlAn, 2,3-FlAn, 1,2-FlAn, 3,4-Per, 7,8-FlAn, 8,9-FlAn, 2,3-TriP, 1,2-TriP, ace, or indeno substituent or their alkyl or aryl substituted derivative.

These materials possess fluorescence efficiencies as high as unity in solutions. Representative materials of this class include:
4-(Diphenylamino)-4′-[4-(diphenylamino)styryl]stilbene;
4-(Di-p-Tolylamino)-4′-[(di-p-tolylamino)styryl]stilbene (Blue-green 2);
4,4′-[(2,5-Dimethoxy-1,4-phenylene)di-2,1-ethenediyl]bis[N,N-bis(4-methylphenyl)benzenamine;
4,4′-(1,4-Naphthalenediyldi-2,1-ethenediyl)bis[N,N-bis(4-methylphenyl)-benzenamine;
3,3′-(1,4-Phenylenedi-2,1-ethenediyl)bis[9-(4-ethylphenyl)-9H-carbazole;
4,4′-(1,4-Phenylenedi-2,1-ethenediyl)bis[N,N-diphenyl-1-naphthalenamine;
4,4′-[1,4-Phenylenebis(2-phenyl-2,1-ethenediyl)]bis[N,N-diphenylbenzenamine];
4,4′,4″-(1,2,4-Benzenetriyltri-2,1-ethenediyl)tris[N,N-diphenylbenzenamine];
9,10-Bis[4-(di-p-tolylamino)styryl]anthracene; or
α,α′-(1,4-Phenylenedimethylidyne)bis[4-(diphenylamino)-1-naphthalene-acetonitrile.

The composition of the light-emitting layer of this invention is such that either the first host component or the second host component can constitute the largest volume fraction of the light-emitting layer. The dopant usually constitutes the smallest volume fraction. The level range for the first host component is from 1 to 99 volume % of the light-emitting layer and typically at least 10 volume % and desirably at least 25 volume % of the light-emitting layer. The preferred range for the first host component is from 5 to 95% by volume. The range for the second host component is from 1 to 99 volume % of the light-emitting layer. The preferred range for the second host component is from 5 to 95% by volume.

In one desirable embodiment the first component comprises a rubrene or a derivative thereof at a level between 25 and 60 volume % of the light-emitting layer and the second component comprises Alq₃ at a level of 75 to 40 volume % of the light-emitting layer. In another desirable embodiment the first component comprises a perylene or a derivative thereof at a level between 25 and 60 volume % of the light-emitting layer and the second component comprises Alq₃ at a level of 75 to 40 volume % of the light-emitting layer.

The concentration range for the dopant is from 0.1% to 10% by volume. The preferred concentration range for the dopant is from 0.5% to 5% by volume. The thickness of the light-emitting layer useful in this invention is between 50 Å and 5000 Å. A thickness in this range is sufficiently large to enable recombination of charge carriers and, therefore, electroluminescence to take place exclusively in this layer. A preferred range is between 100 Å and 1000 Å, where the overall OLED device performance parameters, including drive voltage, are optimal.

A useful method for forming the electron-transporting and light-emitting layers of the present invention is by vapor deposition in a vacuum chamber. This method is particularly useful for fabricating OLED devices, where the layer structure, including the organic layers, can be sequentially deposited on a substrate without significant interference among the layers. The thickness of each individual layer and its composition can be precisely controlled in the deposition process. To produce the desired composition of the light-emitting layer, the rate of deposition for each component is independently controlled using a deposition rate monitor.

Another useful method for forming the electron-transporting and light-emitting layer of the present invention is by spin-coating or by ink-jet printing. This method is particularly useful for fabricating lower-cost OLED devices. Composition of the electron-transporting and light-emitting layer is determined by the concentration of each component in the solutions being coated.

Returning to FIG. 2, hole-transporting layer 231 and electron-transporting layer 233 provide the functions of transporting holes and electrons, respectively, to the light-emitting layer 232. The use of these layers and their material compositions in OLED devices have been disclosed by Tang et al. in commonly assigned U.S. Pat. No. 4,769,292, the disclosure of which is herein incorporated by reference. A typical hole-transporting layer includes the hole-transporting compounds such as N,N′-bis(1-naphthyl)-N,N′-diphenylbenzidine (NPB), N,N′-bis(1-naphthyl)-N,N′-bis(2-naphthyl)benzidine (TNB), and N,N′-bis(3-tolyl)-N,N′-diphenylbenzidine (TPD).

Returning to FIG. 4, hole-injecting layer 431 and electron-injecting layer 435 provide the functions of improving the hole-injection from the anode and electron-injection from the cathode 440, respectively. The use of a hole-injecting layer in OLED devices has been disclosed by Van Slyke et al. in commonly assigned U.S. Pat. No. 4,720,432, the disclosure of which is herein incorporated by reference. The use of an electron-injecting layer has been disclosed by Hung et al. in commonly assigned U.S. Pat. No. 5,776,622, the disclosure of which is herein incorporated by reference.

The OLED device of this invention is typically provided over a supporting substrate where either the cathode or anode can be in contact with the substrate. The electrode in contact with the substrate is conveniently referred to as the bottom electrode. Conventionally, the bottom electrode is the anode, but this invention is not limited to that configuration. The substrate can either be light transmissive or opaque, depending on the intended direction of light emission. The light transmissive property is desirable for viewing the EL emission through the substrate. Transparent glass or plastic is commonly employed in such cases. The substrate can be a complex structure comprising multiple layers of materials. This is typically the case for active matrix substrates wherein TFTs are provided below the OLED layers. It is still necessary that the substrate, at least in the emissive pixelated areas, be comprised of largely transparent materials such as glass or polymers. For applications where the EL emission is viewed through the top electrode, the transmissive characteristic of the bottom support is immaterial, and therefore the substrate can be light transmissive, light absorbing or light reflective. Substrates for use in this case include, but are not limited to, glass, plastic, semiconductor materials such as silicon, ceramics, and circuit board materials. Again, the substrate can be a complex structure comprising multiple layers of materials such as found in active matrix TFT designs. It is necessary to provide in these device configurations a light-transparent top electrode.

When the desired electroluminescent light emission (EL) is viewed through the anode, the anode should be transparent or substantially transparent to the emission of interest. Common transparent anode materials used in this invention are indium-tin oxide (ITO), indium-zinc oxide (IZO) and tin oxide, but other metal oxides can work including, but not limited to, aluminum- or indium-doped zinc oxide, magnesium-indium oxide, and nickel-tungsten oxide. In addition to these oxides, metal nitrides, such as gallium nitride, and metal selenides, such as zinc selenide, and metal sulfides, such as zinc sulfide, can be used as the anode. For applications where EL emission is viewed only through the cathode, the transmissive characteristics of the anode are immaterial and any conductive material can be used, transparent, opaque or reflective. Example conductors for this application include, but are not limited to, gold, iridium, molybdenum, palladium, and platinum. Typical anode materials, transmissive or otherwise, have a work function of 4.1 eV or greater. Desired anode materials are commonly deposited by any suitable way such as evaporation, sputtering, chemical vapor deposition, or electrochemical means. Anodes can be patterned using well known photolithographic processes. Optionally, anodes can be polished prior to application of other layers to reduce surface roughness so as to reduce short circuits or enhance reflectivity.

When light emission is viewed solely through the anode, the cathode used in this invention can be comprised of nearly any conductive material. Desirable materials have effective film-forming properties to ensure effective contact with the underlying organic layer, promote electron injection at low voltage, and have effective lifetime. Useful cathode materials often contain a low work function metal (<4.0 eV) or metal alloy. One useful cathode material is comprised of a Mg:Ag alloy wherein the percentage of silver is in the range of 1 to 20%, as described in U.S. Pat. No. 4,885,221. Another suitable class of cathode materials includes bilayers comprising the cathode and a thin electron-injecting layer (EIL) in contact with an organic layer (e.g., an electron transporting layer (ETL)), the cathode being capped with a thicker layer of a conductive metal. Here, the EIL preferably includes a low work function metal or metal salt, and if so, the thicker capping layer does not need to have a low work function. One such cathode is comprised of a thin layer of LiF followed by a thicker layer of Al as described in U.S. Pat. No. 5,677,572. Other useful cathode material sets include, but are not limited to, those disclosed in U.S. Pat. Nos. 5,059,861, 5,059,862, and 6,140,763.

When light emission is viewed through the cathode, the cathode 113 should be transparent or nearly transparent. For such applications, metals should be thin or one should use transparent conductive oxides, or a combination of these materials. Optically transparent cathodes have been described in more detail in U.S. Pat. Nos. 4,885,211, 5,247,190, 5,703,436, 5,608,287, 5,837,391, 5,677,572, 5,776,622, 5,776,623, 5,714,838, 5,969,474, 5,739,545, 5,981,306, 6,137,223, 6,140,763, 6,172,459, 6,278,236, 6,284,393, and EP 1 076 368. Cathode materials are typically deposited by any suitable method such as evaporation, sputtering, or chemical vapor deposition. When needed, patterning can be achieved through many well known methods including, but not limited to, through-mask deposition, integral shadow masking as described in U.S. Pat. No. 5,276,380 and EP 0 732 868, laser ablation, and selective chemical vapor deposition.

Most OLED devices are sensitive to moisture or oxygen, or both, so they are commonly sealed in an inert atmosphere such as nitrogen or argon, along with a desiccant such as alumina, bauxite, calcium sulfate, clays, silica gel, zeolites, alkaline metal oxides, alkaline earth metal oxides, sulfates, or metal halides and perchlorates. Methods for encapsulation and desiccation include, but are not limited to, those described in U.S. Pat. No. 6,226,890. In addition, barrier layers such as SiOₓ, Teflon, and alternating inorganic/polymeric layers are known in the art for encapsulation. Any of these methods of sealing or encapsulation and desiccation can be used with the EL devices constructed according to the present invention.

OLED devices of this invention can employ various well known optical effects in order to enhance their emissive properties if desired. This includes optimizing layer thicknesses to yield maximum light transmission, providing dielectric mirror structures, replacing reflective electrodes with light-absorbing electrodes, providing anti-glare or antireflection coatings over the display, providing a polarizing medium over the display, or providing colored, neutral density, or color-conversion filters over the display. Filters, polarizers, and anti-glare or antireflection coatings can be specifically provided over the EL device or as part of the EL device.

Embodiments of the invention can provide advantageous features such as higher luminous yield, low drive voltage, and high power efficiency, or reduced sublimation temperatures. Embodiments of the compounds useful in the invention can provide a wide range of hues including those useful in the emission of white light (directly or through filters to provide multicolor displays). Embodiments of the invention can also provide an area lighting device. The invention and its advantages can be better appreciated by the following examples.

### EXAMPLES

### Examples T1-T8

### Test Devices

OLED devices T1-T8 (Table T1) were prepared as follows. A glass substrate coated with ˜250 Å transparent indium-tin-oxide (ITO) conductive layer was cleaned and dried using a commercial glass scrubber tool. The ITO surface was subsequently treated with oxygen plasma to condition the surface as an anode. Over the ITO was deposited a ˜10 Å thick hole-injecting layer of fluorocarbon (CFₓ) by plasma-assisted deposition of CHF₃. The following layers were deposited in the following sequence by sublimation from heated crucible boats in a conventional vacuum deposition chamber under a vacuum of approximately 10⁻⁶ Torr (Table T1):
(1) the HTL, 750 Å thick, composed of NPB;
(2) the light-emitting layer, 375 Å thick, composed of AlQ;
(3) the ETL, 375 Å thick, composed of either AlQ (reference device T1), AlQ doped with 3.7% Li, or a test ETL material, which is either undoped or doped with 3.7% Li;
(4) the cathode, 2,100 Å thick, including an alloy of magnesium and silver with a Mg:Ag volume ratio of 20:1.

Following that the devices were encapsulated in a nitrogen atmosphere along with calcium sulfate as a desiccant.

The EL characteristics of these devices were evaluated using a constant current source and a photometer. The drive voltage, EL efficiency in cd/A and W/A, and CIE coordinates at DC current densities ranging from relatively low, 0.5 mA/cm², to relatively high, 100 mA/cm², were measured and are reported at 20 mA/cm² in Table T1.

It should be noted that the drive voltage given in Table T1 is not corrected for the contact resistance and the ITO lead resistance which means that the voltage drop across the OLED device itself is lower by ˜1.5 V.

As can be seen from Table T1, the voltage drop across the improved ETL materials of devices T2-T8 is lower than that for the reference device T1 having an ordinary ETL made of AlQ. As can be further seen from Table T1, the EL efficiencies for the devices T2-T8 are largely unaffected compared to the reference device T1. Thus, the ETL materials and compositions of devices T2-T8 satisfy the necessary requirements of this invention.

TABLE T1
Device data at 20 mA/cm²: test devices defining ETL materials
(device structure: glass 1.1 mm|250 Å ITO|10 Å CFₓ|
750 Å NPB|375 Å A1Q|375 Å test ETL material|2,000 Å Mg:Ag (20:1)

| | HTL- | LEL- | ETL- | | | | | |
|---|---|---|---|---|---|---|---|---|
| | material and | materials and | material and | Voltage, | V/Å in | Efficiency, | Efficiency, | CIEₓ |
| Device | thickness, Å | thickness, Å | thickness, Å | V | ETL | cd/A | W/A | CIE_{y} |
| T1 | NPB, 750 | A1Q, 375 | A1Q, 375 | 8.0 | 0.0070 | 3.0 | 0.021 | 0.340 |
| | | | | | | | | 0.550 |
| T2 | NPB, 750 | A1Q, 375 | Triazine-1, 375 | 7.2 | 0.0049 | 3.1 | 0.022 | 0.356 |
| | | | | | | | | 0.544 |
| T3 | NPB, 750 | A1Q, 375 | A1Q + 3.7% Li, 375 | 7.0 | 0.0043 | 3.0 | 0.022 | 0.341 |
| | | | | | | | | 0.552 |
| T4 | NPB, 750 | A1Q, 375 | GaQ + 3.7% Li, 375 | 6.5 | 0.0030 | 2.9 | 0.020 | 0.343 |
| | | | | | | | | 0.549 |
| T5 | NPB, 750 | A1Q, 375 | BPhen, 375 | 7.5 | 0.0057 | 3.1 | 0.023 | 0.335 |
| | | | | | | | | 0.550 |
| T6 | NPB, 750 | A1Q, 375 | BPhen + 3.7% Li, 375 | 5.7 | 0.0009 | 3.0 | 0.021 | 0.334 |
| | | | | | | | | 0.552 |
| T7 | NPB, 750 | A1Q, 375 | Pyr-3 + 3.7% Li, 375 | 5.4 | 0.0001 | 3.1 | 0.023 | 0.325 |
| | | | | | | | | 0.547 |
| T8 | NPB, 750 | A1Q, 375 | TBPI + 3.7% Li, 375 | 5.7 | 0.0009 | 2.9 | 0.020 | 0.352 |
| | | | | | | | | 0.554 |

### Device Example 1 (Inventive)

An OLED device (Device 1) was prepared as follows. A glass substrate was coated with about an 850 Å transparent indium-tin-oxide (ITO) conductive layer and was cleaned and dried using a commercial glass scrubber tool. The ITO surface was subsequently treated with an oxidative plasma to condition the surface as an anode. Over the ITO was deposited a 10 Å thick hole-injecting layer of fluorocarbon (CFx) by plasma-assisted deposition of CHF₃. The following layers were deposited in the following sequence by thermal evaporation from heated crucible boats in a conventional vacuum deposition chamber under a vacuum of approximately 10⁻⁶ Torr: (1) a hole-transporting layer, 750 Å thick, including NPB; (2) a light-emitting layer, 600 Å thick, including the first host Dibenzo[b,k]perylene (DBP) (32.5 volume %) and the second host component, Alq₃ (66.5 volume %) and containing 1.0 volume % light-emitting dopant DCJTB; (3) an electron-transporting layer (ETL), 375 Å thick, including AlQ₃, and 3.6 volume % Li metal; and (4) a cathode, approximately 2200 Å thick, including an alloy of magnesium and silver with a Mg:Ag volume ratio of about 10:1. Following that the devices were encapsulated in a nitrogen atmosphere along with calcium sulfate as a desiccant

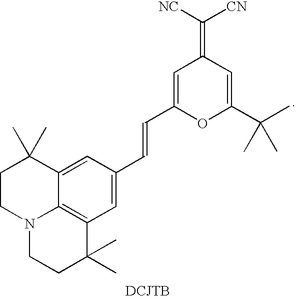

### Device Example 2 (Comparative)

An OLED comparative device (Device 2) was prepared in the same manner as Device 1, except the ETL did not contain Li.

### Device Example 3 (Comparative)

An OLED comparative device (Device 3) was prepared in the same manner as Device 1, except the light-emitting layer included only one host component, Alq₃ (99%), and contained 1.0 volume % light-emitting dopant DCJTB.

### Device Example 4 (Comparative)

An OLED comparative device (Device 4) was prepared in the same manner as Device 3, except the ETL did not contain Li.

Table 1A summarizes key components of the device structure of Examples 1-4. The cells thus formed were tested for efficiency and color at an operating current of 20 mA/cm² and the results are reported in Table 1B in the form of voltage (V), output luminance yield (cd/A), efficiency (W/A),, and CIE coordinates. Room temperature lifetime (reported as RT Lifetime T₅₀ in hours in Table 1B) was measured as the amount of time necessary to operate the cells at 40 mA/cm² at room temperature (approximately 23° C.), until the luminance had decreased to 50% of the original luminance. Likewise, 70° C. lifetime was measured as the amount of time necessary to operate the cells at 20 mA/cm² at a temperature of 70° C., until the luminance had decreased to 50% of the original luminance.

TABLE 1A
Key Components of Devices 1-4

| | | | | | DCJTB | ETL | |
|---|---|---|---|---|---|---|---|
| | | LEL | | | Dopant | Alq₃ | % Li |
| | | Thickness | % DBP | % Alq₃ | (Level) | Thickness | Metal |
| Device | Type | (Å) | (First Host) | (Second Host) | % | (Å) | Level |
| 1 | Inventive | 600 | 32.5 | 66.5 | 1.0 | 375 | 3.6 |
| 2 | Comparative | 600 | 32.5 | 66.5 | 1.0 | 375 | 0 |
| 3 | Comparative | 600 | 0 | 99 | 1.0 | 375 | 3.6 |
| 4 | Comparative | 600 | 0 | 99 | 1.0 | 375 | 0 |

TABLE 1B
Testing Results For Devices 1-4

| | | | | | | RT | 70° C. |
|---|---|---|---|---|---|---|---|
| | | Voltage | Efficiency | Efficiency | CIEₓ | Lifetime | Lifetime |
| Device | Type | (V) | (cd/A) | (W/A) | CIE_{y} | T₅₀ (h) | T₅₀ (h) |
| 1 | Inventive | 8.0 | 3.6 | 0.066 | 0.650 | 35000 | — |
| | | | | | 0.347 | | |
| 2 | Comparative | 7.7 | 3.3 | 0.055 | 0.641 | 25000 | — |
| | | | | | 0.350 | | |
| 3 | Comparative | 7.1 | 3.0 | 0.037 | 0.596 | — | 600 |
| | | | | | 0.395 | | |
| 4 | Comparative | 9.0 | 2.5 | 0.034 | 0.614 | — | 580 |
| | | | | | 0.378 | | |

As can be seen from Table 1B, besides a reduction in voltage, there was a negligible difference between Devices 3 and 4. Both of these devices contained a light-emitting layer containing one host, Alq, and the dopant DCJTB. The only difference between these two devices was that Device 3 had Li doped into the ETL while Device 4 did not. When the light-emitting layer contained two host materials as in Device 2, efficiency and CIE color coordinates were vastly improved over those of both Devices 3 and 4. Inventive Device 1, which had the same configuration as Device 2 except the ETL was doped with Li, had lifetime that is significantly improved over that for Device 2. Moreover, inventive Device 1 had improved efficiency and CIE color coordinates compared to those of Device 2. It is clear from these data that inventive device 1 has superior device performance data over comparative devices.

### Device Example 5 (Inventive)

An OLED device (Device 5) was prepared in the same manner as Device 1, except the light-emitting layer contained a first host component Rubrene (39.5 volume %) and a second host component Alq (59.5 volume %), and contained 1 volume % of the light-emitting dopant DCJTB.

### Device Example 6 (Comparative)

An OLED comparative device (Device 6) was prepared in the same manner as Device 5, except the ETL did not contain Li.

Table 2A summarizes key components of the device structure of examples 5 and 6. The cells, thus formed, were tested for efficiency and color at an operating current of 20 mA/cm² and the results are reported in Table 2B in the form of voltage (V), output luminance yield (cd/A), efficiency (W/A), and CIE coordinates. Room temperature lifetime (reported as RT Lifetime T₅₀ in hours in Table 2B) was measured as the amount of time necessary to operate the cells at 40 mA/cm² at room temperature (approximately 23° C.), until the luminance had decreased to 50% of the original luminance.

TABLE 2A
Key Components of Devices 5 and 6

| | | | | | DCJTB | ETL | |
|---|---|---|---|---|---|---|---|
| | | LEL | | | Dopant | Alq₃ | % Li |
| | | Thickness | % Rubrene | % Alq₃ | (Level) | Thickness | Metal |
| Device | Type | (Å) | (First Host) | (Second Host) | % | (Å) | Level |
| 5 | Inventive | 600 | 39.5 | 59.5 | 1.0 | 375 | 3.6 |
| 6 | Comparative | 600 | 39.5 | 59.5 | 1.0 | 375 | 0 |

TABLE 2B
Testing Results For Devices 5 and 6

| | | Vol- | | | | RT |
|---|---|---|---|---|---|---|
| | | Type | Efficiency | Efficiency | CIEₓ | Lifetime |
| Device | Type | (V) | (cd/A) | (W/A) | CIE_{y} | T₅₀ (h) |
| 5 | Inventive | 5.7 | 5.3 | 0.079 | 0.635 | 13000 |
| | | | | | 0.360 | |
| 6 | Comparative | 8.0 | 5.1 | 0.081 | 0.640 | 8000 |
| | | | | | 0.360 | |

As can be seen from Table 2B, efficiency and CIE color coordinates are approximately the same for both Devices 5 and 6. However, inventive Device 5 has lower voltage and improved lifetime compared to Device 6. Thus, Device 5 shows superior performance over all comparative devices.

### Device Example 7 (Inventive)

An OLED device (Device 7) was prepared as follows. A glass substrate was coated with about an 850 Å transparent indium-tin-oxide (ITO) conductive layer and was cleaned and dried using a commercial glass scrubber tool. The ITO surface was subsequently treated with an oxidative plasma to condition the surface as an anode. Over the ITO was deposited a 10 Å thick hole-injecting layer of fluorocarbon (CFx) by plasma-assisted deposition of CHF₃. The following layers were deposited in the following sequence by thermal evaporation from heated crucible boats in a conventional vacuum deposition chamber under a vacuum of approximately 10⁻⁶ Torr: (1) a hole-transporting layer, 750 Å thick, including NPB; (2) a light-emitting layer, 700 Å thick, including the first host Rubrene (44.8 volume %) and the second host component, Alq₃ (54.8 volume %) and containing 0.4 volume % light-emitting dopant Red 2; (3) an electron-transporting layer (ETL), 375 Å thick, including AlQ₃, and 3.6 volume % Li metal; and (4) a cathode, approximately 2200 Å thick, including an alloy of magnesium and silver with a Mg:Ag volume ratio of about 10:1. Following that, the devices were encapsulated in a nitrogen atmosphere along with calcium sulfate as a desiccant

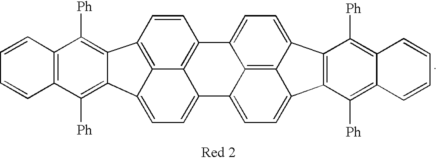

### Device Example 8 (Comparative)

An OLED comparative device (Device 8) was prepared in the same manner as Device 7, except the ETL did not contain Li.

Table 3A summarizes key components of the device structure of examples 7 and 8. The cells, thus formed, were tested for efficiency and color at an operating current of 20 mA/cm² and the results are reported in Table 3B in the form of voltage (V), output luminance yield (cd/A), efficiency (W/A), and CIE coordinates. Room temperature lifetime (reported as RT Lifetime T₅₀ in hours in Table 3B) was measured as the amount of time necessary to operate the cells at 40 mA/cm² at room temperature (approximately 23° C.), until the luminance had decreased to 50% of the original luminance.

TABLE 3A
Key Components of Devices 7 and 8

| | | | | | Red 2 | ETL | |
|---|---|---|---|---|---|---|---|
| | | LEL | | | Dopant | Alq₃ | % Li |
| | | Thickness | % Rubrene | % Alq₃ | (Level) | Thickness | Metal |
| Device | Type | (Å) | (First Host) | (Second Host) | % | (Å) | Level |
| 7 | Inventive | 700 | 44.8 | 54.8 | 0.4 | 375 | 3.6 |
| 8 | Comparative | 700 | 44.8 | 54.8 | 0.4 | 375 | 0 |

TABLE 3B
Testing Results For Devices 7 and 8

| | | Vol- | | | | RT |
|---|---|---|---|---|---|---|
| | | tage | Efficiency | Efficiency | CIEₓ | Lifetime |
| Device | Type | (V) | (cd/A) | (W/A) | CIE_{y} | T₅₀ (h) |
| 7 | Inventive | 6.5 | 5.3 | 0.086 | 0.663 | 50000 |
| | | | | | 0.335 | |
| 8 | Comparative | 7.7 | 5.0 | 0.075 | 0.645 | 15000 |
| | | | | | 0.348 | |

As can be seen from Table 3B, Inventive Device 7 has lower voltage, higher efficiency, improved CIE color coordinates, and a greater than 3 times improvement in lifetime versus Comparative Device 8.

### Device Example 9 (Inventive)

An OLED device (Device 9) was prepared as follows. A glass substrate was coated with about an 850 Å transparent indium-tin-oxide (ITO) conductive layer and was cleaned and dried using a commercial glass scrubber tool. The ITO surface was subsequently treated with an oxidative plasma to condition the surface as an anode. Over the ITO was deposited a 10 Å thick hole-injecting layer of fluorocarbon (CFx) by plasma-assisted deposition of CHF₃. The following layers were deposited in the following sequence by thermal evaporation from heated crucible boats in a conventional vacuum deposition chamber under a vacuum of approximately 10⁻⁶ Torr: (1) a hole-transporting layer, 750 Å thick, including NPB; (2) a light-emitting layer, 550 Å thick, including the first host Dibenzo[b,k]perylene (DBP) (32.6 volume %) and the second host component, Alq₃ (66.6 volume %) and containing 0.8 volume % of the light-emitting dopant C545T; (3) an electron-transporting layer (ETL), 375 Å thick, including AlQ₃, and 3.6 volume % Li metal; and (4) a cathode, approximately 2200 Å thick, including an alloy of magnesium and silver with a Mg:Ag volume ratio of about 10:1. Following that, the devices were encapsulated in a nitrogen atmosphere along with calcium sulfate as a desiccant

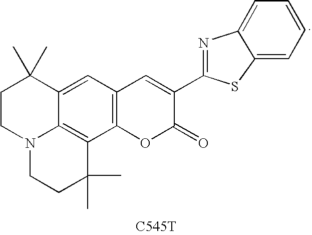

### Device Example 10 (Comparative)

An OLED comparative device (Device 10) was prepared in the same manner as Device 9, except the ETL layer did not contain Li.

### Device Example 11 (Comparative)

An OLED comparative device (Device 11) was prepared in the same manner as Device 9, except the light-emitting layer was 200 Å thick, included only one host component, Alq₃ (99.2 volume %), and contained 0.8 volume % light-emitting dopant C545T, and the ETL which was 400 Å thick, included AlQ₃, and 3.6 volume % Li metal.

### Device Example 12 (Comparative)

An OLED comparative device (Device 12) was prepared in the same manner as Device 9, except the light-emitting layer was 375 Å thick, included only one host component, Alq₃ (99.2 volume %) and contained 0.8 volume % light-emitting dopant C545T. Additionally, the ETL layer was 375 Å thick and did not contain Li.

Table 4A summarizes key components of the device structure of Examples 9-12. The cells thus formed were tested for efficiency and color at an operating current of 20 mA/cm² and the results are reported in Table 4B in the form of voltage (V), output luminance yield (cd/A), efficiency (W/A), and CIE coordinates. Room temperature lifetime (reported as RT Lifetime T₅₀ in hours in Table 4B) was measured as the amount of time necessary to operate the cells at 40 mA/cm² at room temperature (approximately 23° C.), until the luminance had decreased to 50% of the original luminance.

TABLE 4A
Key Components of Devices 9-12

| | | | | | C545T | ETL | |
|---|---|---|---|---|---|---|---|
| | | LEL | | | Dopant | Alq₃ | % Li |
| | | Thickness | % DBP | % Alq₃ | (Level) | Thickness | Metal |
| Device | Type | (Å) | (First Host) | (Second Host) | % | (Å) | Level |
| 9 | Inventive | 550 | 32.6 | 66.6 | 0.8 | 375 | 3.6 |
| 10 | Comparative | 550 | 32.6 | 66.6 | 0.8 | 375 | 0 |
| 11 | Comparative | 200 | 0 | 99.2 | 0.8 | 350 | 3.6 |
| 12 | Comparative | 750 | 0 | 99.2 | 0.8 | 375 | 0 |

TABLE 4B
Testing Results For Devices 9-12

| | | Vol- | | | | RT |
|---|---|---|---|---|---|---|
| | | Type | Efficiency | Efficiency | CIEₓ | Lifetime |
| Device | tage | (V) | (cd/A) | (W/A) | CIE_{y} | T₅₀ (h) |
| 9 | Inventive | 7.0 | 11.0 | 0.066 | 0.325 | 30000 |
| | | | | | 0.636 | |
| 10 | Comparative | 8.3 | 10.0 | 0.062 | 0.321 | 20000 |
| | | | | | 0.632 | |
| 11 | Comparative | 5.8 | 10.8 | 0.066 | 0.284 | 760 |
| | | | | | 0.654 | |
| 12 | Comparative | 8.4 | 9.7 | 0.060 | 0.292 | 550 |
| | | | | | 0.646 | |

As can be seen from Table 4B, Inventive Device 9, which has a Li doped ETL, has lower voltage, higher efficiency and significantly improved lifetime versus comparative Device 10 (same configuration except ETL is not doped with Li). In fact, lifetime has been increased 1.5 times from 20,000 hours to 30,000 hours when Li is incorporated into the ETL. Comparing Devices 11 and 12 illustrates that the device with Li incorporated into the ETL has lower voltage, higher efficiency and increased lifetime. In fact, the lifetime increases from 550 hours to 760 hours when the ETL is doped with Li. This also is an increase by approximately 1.5 times. However, the absolute magnitude of this increase is significantly smaller than that for devices 9 and 10. From these data, it is evident that Inventive Device 9 is superior to all the comparative devices.

### Device Example 13 (Inventive)

An OLED device (Device 13) was prepared as follows. A glass substrate was coated with about an 850 Å transparent indium-tin-oxide (ITO) conductive layer and was cleaned and dried using a commercial glass scrubber tool. The ITO surface was subsequently treated with an oxidative plasma to condition the surface as an anode. Over the ITO was deposited a 10 Å thick hole-injecting layer of fluorocarbon (CFx) by plasma-assisted deposition of CHF₃. The following layers were deposited in the following sequence by thermal evaporation from heated crucible boats in a conventional vacuum deposition chamber under a vacuum of approximately 10⁻⁶ Torr: (1) a hole-transporting layer, 750 Å thick, including NPB; (2) a light-emitting layer, 700 Å thick, including the first host Rubrene (44.8 volume %) and the second host component, Alq₃ (54.8 volume %) and containing 0.4 volume % of the light-emitting dopant Red 2; (3) an electron-transporting layer (ETL) that is divided into two sublayers, a first sublayer (a) 100 Å thick, including Triazine 1 and a second sublayer (b) 275 Å thick, including AlQ₃, and 3.6 volume % Li metal; and (4) a cathode, approximately 2200 Å thick, including an alloy of magnesium and silver with a Mg:Ag volume ratio of about 10:1. Following that, the devices were encapsulated in a nitrogen atmosphere along with calcium sulfate as a desiccant

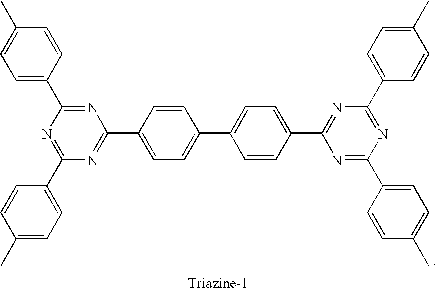

### Device Example 14 (Inventive)

An OLED device (Device 14) was prepared in the same manner as Device 13, except the first sublayer (a) was 100 Å thick and included only Alq.

Table 5A summarizes key components of the device structure of Examples 13 and 14, along with comparative Device 8 which does not contain a Li doped ETL. The cells thus formed were tested for efficiency and color at an operating current of 20 mA/cm² and the results are reported in Table 5B in the form of voltage (V), output luminance yield (cd/A), efficiency (W/A), and CIE coordinates. Room temperature lifetime (reported as RT Lifetime T₅₀ in hours in Table 5B) was measured as the amount of time necessary to operate the cells at 40 mA/cm² at room temperature (approximately 23° C.), until the luminance had decreased to 50% of the original luminance.

TABLE 5A
Key Components of Devices 13, 14, and 8

| | | | | | Red 2 | ETL | ETL | |
|---|---|---|---|---|---|---|---|---|
| | | LEL | % | | Dopant | sublayer (a) | sublayer (b) | % Li |
| | | Thickness | Rubrene | % Alq₃ | (Level) | Thickness | Thickness | Metal Level |
| Device | Type | (Å) | (First Host) | (Second Host) | % | (Å) | (Å) | sublayer (b) |
| 13 | Inventive | 700 | 44.8 | 54.8 | 0.4 | 100 | 275 | 3.6 |
| 14 | Inventive | 700 | 44.8 | 54.8 | 0.4 | 100 | 275 | 3.6 |
| 8 | Comparative | 700 | 44.8 | 54.8 | 0.4 | 0 | 375 | 0 |

TABLE 5B
Testing Results For Devices 13, 14, and 8

| | | Vol- | | | | RT |
|---|---|---|---|---|---|---|
| | | tage | Efficiency | Efficiency | CIEₓ | Lifetime |
| Device | Type | (V) | (cd/A) | (W/A) | CIE_{y} | T₅₀ (h) |
| 13 | Inventive | 6.3 | 5.7 | 0.095 | 0.664 | 50000 |
| | | | | | 0.334 | |
| 14 | Inventive | 7.6 | 6.0 | 0.095 | 0.658 | 25000 |
| | | | | | 0.340 | |
| 8 | Comparative | 7.7 | 5.0 | 0.075 | 0.645 | 15000 |
| | | | | | 0.348 | |

As can be seen from Table 5B, Inventive Devices 13 and 14 have significantly improved efficiencies and lifetimes versus those of Comparative Device 8 which does not have a Li doped ETL.

The invention has been described in detail with particular reference to certain preferred embodiments thereof, but it will be understood that variations and modifications can be effected within the spirit and scope of the invention.

1. An organic light-emitting device, comprising:
a) a substrate;
b) an anode and a cathode disposed over the substrate;
c) a light-emitting layer disposed between the anode and the cathode wherein the light-emitting layer includes a host and at least one dopant;
d) the host of the light-emitting layer being selected to include a solid organic material including a mixture of at least two components wherein:
i) the first host component is an organic compound that is capable of transporting electrical charges and also forms an aggregate; and
ii) the second host component is an organic compound that is capable of transporting electrical charges and upon mixing with the first host component is capable of forming a continuous and substantially pin-hole-free layer; and
e) the dopant of the light-emitting layer being selected to produce colored light; and
f) an electron-transporting layer disposed between the light-emitting layer and the cathode for providing improved electron injection and transport.

2. The organic light-emitting device of claim 1 wherein the electron-transporting layer includes at least one alkali metal or alkaline earth metal.

3. The organic light-emitting device of claim 2 wherein the electron-transporting layer includes an oxinoid compound.

4. The organic light-emitting device of claim 3 wherein the electron-transporting layer includes AlQ₃, GaQ₃, InQ₃, ScQ₃, ZnQ₂, BeBq₂ (bis(10-hydroxybenzo[h]quinolinato)beryllium), Al(4-MeQ)₃, Al(2-MeQ)₃, Al(2,4-Me₂Q)₃, Ga(4-MeQ)₃, Ga(2-MeQ)₃, Ga(2,4-Me₂Q)₃, Mg(2-MeQ)₂, or Al(2-MeQ)₂(X) where X is any aryloxy, alkoxy, arylcaboxylate, and heterocyclic carboxylate group.

5. The organic light-emitting device of claim 2 wherein the electron-transporting layer includes a triazine compound.

6. The organic light-emitting device of claim 5 wherein the electron-transporting layer includes Triazine 1.

7. The organic light-emitting device of claim 2 wherein the electron-transporting layer includes a phenanthroline compound.

8. The organic light-emitting device of claim 7 wherein the electron-transporting layer includes BPHEN.

9. The organic light-emitting device of claim 7 wherein the electron-transporting layer includes BCP.

10. The organic light-emitting device of claim 2 wherein Li is included in the electron-transporting layer at a level of 0.5 to 10 volume % of the electron-transporting layer.

11. The organic light-emitting device of claim 2 wherein Cs is included in the electron-transporting layer at a level of 0.5 to 30 volume % of the electron transporting layer.

12. The organic light-emitting device of claim 2 wherein the molar ratio of alkali metal or alkaline earth metal to electron-transporting material in the electron-transporting layer is from 0.1:1 to 2:1.

13. The organic light-emitting device of claim 2 wherein the electron-transporting layer is further divided into at least two sublayers wherein at least one sublayer includes an alkali metal or alkaline earth metal.

14. The organic light-emitting device of claim 13 wherein the material comprising the sublayer adjacent to the light-emitting layer has:
i′) a LUMO level equal to or lower than that of the second host component of the light-emitting layer, and
ii′) a HOMO level lower than that of the second host component of the light-emitting layer, and does not include an alkali metal or alkaline earth metal.

15. The organic light-emitting device of claim 13 wherein the sublayer adjacent to the light-emitting layer does not include an alkali metal or alkaline earth metal, and wherein the sublayer adjacent to the cathode includes at least one alkali metal or alkaline earth metal.

16. The organic light-emitting device of claim 14 wherein the sublayer adjacent to the light-emitting layer includes a Triazine compound.

17. The organic light-emitting device of claim 16 wherein the sublayer includes Triazine 1.

18. The organic light-emitting device of claim 14 wherein the sublayer adjacent to the light-emitting layer includes a phenanthroline compound.

19. The organic light-emitting device of claim 18 wherein the sublayer includes BPHEN.

20. The organic light-emitting device of claim 18 wherein the sublayer includes BCP.

21. The organic light-emitting device of claim 14 wherein the sublayer adjacent to the light-emitting layer includes an oxinoid compound.

22. The organic light-emitting device of claim 21 wherein the sublayer includes AlQ₃, GaQ₃, InQ₃, ScQ₃, ZnQ₂, BeBq₂ (bis(10-hydroxybenzo[h]quinolinato)beryllium), Al(4-MeQ)₃, Al(2-MeQ)₃, Al(2,4-Me₂Q)₃, Ga(4-MeQ)₃, Ga(2-MeQ)₃, Ga(2,4-Me₂Q)₃, Mg(2-MeQ)₂, or Al(2-MeQ)₂(X) where X is any aryloxy, alkoxy, arylcaboxylate, and heterocyclic carboxylate group.

23. The organic light-emitting device of claim 13 wherein the sublayer adjacent to the cathode includes Li.

24. The organic light-emitting device of claim 13 wherein the sublayer adjacent to the cathode includes Cs.

25. The organic light-emitting device of claim 13 wherein the sublayer adjacent to the cathode includes a phenanthroline compound.

26. The organic light-emitting device of claim 25 wherein the sublayer includes BPHEN.

27. The organic light-emitting device of claim 25 wherein the sublayer includes BCP.

28. The organic light-emitting device of claim 13 wherein the sublayer adjacent to the cathode includes an oxinoid compound.

29. The organic light-emitting device of claim 28 wherein the sublayer includes AlQ₃, GaQ₃, InQ₃, ScQ₃, ZnQ₂, BeBq₂ (bis(10-hydroxybenzo[h]quinolinato)beryllium), Al(4-MeQ)₃, Al(2-MeQ)₃, Al(2,4-Me₂Q)₃, Ga(4-MeQ)₃, Ga(2-MeQ)₃, Ga(2,4-Me₂Q)₃, Mg(2-MeQ)₂, or Al(2-MeQ)₂(X) where X is any aryloxy, alkoxy, arylcaboxylate, and heterocyclic carboxylate group.

30. The organic light-emitting device of claim 2 wherein the aggregate is a dimer in either ground electronic state or excited electronic state.

31. The organic light-emitting device of claim 2 wherein the first host component is an organic compound that includes a benzenoid hydrocarbon.

32. The organic light-emitting device of claim 2 wherein the first host component is an organic compound that includes a heterocycle.

33. The organic light-emitting device of claim 2 wherein the dopant has an energy gap less than or equal to those of the first host component and the second host component.

34. The organic light-emitting device of claim 2 wherein the dopant concentration in the light-emitting layer is between 0.1 and 10% by volume.

35. The organic light-emitting device of claim 2 wherein the first host component is a naphthopyrene or a derivative thereof.

36. The organic light-emitting device of claim 2 wherein the first host component is naphthacene or a derivative thereof.

37. The organic light-emitting device of claim 2 wherein the first host component is perylene or a derivative thereof.

38. The organic light-emitting device of claim 2 wherein the first host component is anthracene or a derivative thereof.

39. The organic light-emitting device of claim 2 wherein the first host component is anthanthrene or a derivative thereof.

40. The organic light-emitting device of claim 2 wherein the first host component is benzo[ghi]perylene or a derivative thereof.

41. The organic light-emitting device of claim 2 wherein the first host component is benzoperylene or a derivative thereof.

42. The organic light-emitting device of claim 2 wherein the first host component is a dibenzoperylene or a derivative thereof.

43. The organic light-emitting device of claim 2 wherein the first host component is tetraphene or a derivative thereof.

44. The organic light-emitting device of claim 2 wherein the first host component is picene or a derivative thereof.

45. The organic light-emitting device of claim 2 wherein the first host component is a naphthoperylene or dinaphthoperylene or a derivative thereof.

46. The organic light-emitting device of claim 2 wherein the first host component includes a benzenoid hydrocarbon or a derivative thereof substituted with a donor or an acceptor moiety or both.

47. The organic light-emitting device of claim 2 wherein the second host component includes a benzenoid hydrocarbon or a derivative thereof substituted with a donor or an acceptor moiety or both.

48. The organic light-emitting device of claim 2 wherein the second host component includes an oxinoid compound.

49. The organic light-emitting device of claim 48 wherein the second host component includes AlQ₃, GaQ₃, InQ₃, ScQ₃, ZnQ₂, BeBq₂ (bis(10-hydroxybenzo[h]quinolinato)beryllium), Al(4-MeQ)₃, Al(2-MeQ)₃, Al(2,4-Me₂Q)₃, Ga(4-MeQ)₃, Ga(2-MeQ)₃, Ga(2,4-Me₂Q)₃, Mg(2-MeQ)₂, or Al(2-MeQ)₂(X) where X is any aryloxy, alkoxy, arylcaboxylate, and heterocyclic carboxylate group.

50. The organic light-emitting device of claim 2 wherein the second host component includes an anthracene moiety.

51. The organic light-emitting device of claim 50 wherein the second host component includes:
2-(1,1-dimethylethyl)-9,10-bis(2-naphthalenyl)anthracene (TBADN);
9,10-bis(2-naphthalenyl)anthracene (ADN);
9,10-bis(1-naphthalenyl)anthracene;
9,10-Bis[4-(2,2-diphenylethenyl)phenyl]anthracene;
9,10-Bis([1,1′:3′,1″-terphenyl]-5′-yl)anthracene;
9,9′-Bianthracene;
10,10′-Diphenyl-9,9′-bianthracene;
10,10′-Bis([1,1′:3′, 1″-terphenyl]-5′-yl)-9,9′-bianthracene;
2,2′-Bianthracene;
9,9′,10,10′-Tetraphenyl-2,2′-bianthracene;
9,10-Bis(2-phenylethenyl)anthracene; or
9-Phenyl-10-(phenylethynyl)anthracene.

52. The organic light-emitting device of claim 2 wherein the second host component includes an amine moiety.

53. The organic light-emitting device of claim 52 wherein the second host component includes:
N,N′-bis(1-naphthalenyl)-N,N′-diphenylbenzidine (NPB);
N,N′-bis(1-naphthalenyl)-N,N′-bis(2-naphthalenyl)benzidine (TNB);
N,N′-bis(3-methylphenyl)-N;N′-diphenylbenzidine (TPD); or
N,N′-Bis(N″,N″-diphenylaminonaphthalen-5-yl)-N,N′-diphenyl-1,5-diaminonaphthalene (CAS 503624-47-3).

54. The organic light-emitting device of claim 2 wherein the second host component includes a fluorene moiety.

55. The organic light-emitting device of claim 54 wherein the second host component includes:
2,2′,7,7′-Tetraphenyl-9,9′-spirobi[9H-fluorene];
2,2′,7,7′-Tetra-2-phenanthrenyl-9,9′-spirobi[9H-fluorene];
2,2′-Bis (4-N,N-diphenylaminophenyl)-9,9′-spirobi[9H-fluorene] (CAS 503307-40-2);
4′-Phenyl-spiro[fluorene-9,6′-[6H]indeno[1,2-j]fluoranthene];
2,3,4-Triphenyl-9,9′-spirobifluorene;
11,11′-Spirobi[11H-benzo[b]fluorene];
9,9′-Spirobi[9H-fluorene]-2,2′-diamine;
9,9′-Spirobi[9H-fluorene]-2,2′-dicarbonitrile;
2′,7′-Bis([1′-biphenyl]-4-yl)-N,N,N′,N′-tetraphenyl-9,9′-spirobi[9H-fluorene]-2,7-diamine;
9,9,9′,9′,9″,9″-Hexaphenyl-2,2′:7′,2″-ter-9H-fluorene;
2,7-Bis([1,1′-biphenyl]-4-yl)-9,9′-spirobi[9H-fluorene];
2,2′,7,7′-tetra-2-Naphthalenyl-9,9′-spirobi[9H-fluorene]; or
9,9′-[(2,7-Diphenyl-9H-fluoren-9-ylidene)di-4,1-phenylene]bis-anthracene.

56. The organic light-emitting device of claim 2 wherein the second host component includes a naphthacene moiety.

57. The organic light-emitting device of claim 56 wherein the second host component includes:
5,6,11,12-Tetraphenylnaphthacene (rubrene);
5,12-Bis(2-naphthyl)-6,11-diphenyltetracene;
5,12-Bis(2-mesityl)-6,11-diphenyltetracene;
5,12-Bis(1-naphthyl)-6,11-diphenyltetracene;
5,6,11,12-Tetrakis(2-naphthyl)tetracene;
10,10′-[(6,11-Diphenyl-5,12-naphthacenediyl)di-4,1-phenylene]-bis[2,3,6,7-tetrahydro-1H,5H-benzothiazolo[5,6,7-ij]quinolizine;
9,10,15,16-Tetraphenyl-dibenzo[a,c]naphthacene;
5,6,13,14-Tetraphenylpentacene;
4,4′-(8,9-Dimethyl-5,6,7,10,11,12-hexaphenyl-1,4-naphthacenediyl)bis-benzonitrile;
4,4′-(8,9-Dimethoxy-5,6,7,10,11,12-hexaphenyl-1,4-naphthacenediyl)bis[N,N-diphenylbenzenamine];
1,2,3,5,6,11,12-Heptaphenylnaphthacene;
1,4,5,6,7,10,11,12-Octaphenylnaphthacene;
6,11-diphenyl-5,12-bis(4′-N,N-diphenylaminophenyl)naphthacene;
7,8,15,16-Tetraphenyl-benzo[a]pentacene;
2,3,5,6,11,12-Hexaphenylnaphthacene;
6,11-diphenyl-5,12-bis(4′-cyanophenyl)naphthacene;
6,11-diphenyl-5,12-bis(4′-(2-thienyl)phenyl)naphthacene; or
9,10,19,20-Tetraphenyl-tetrabenzo[a,c,j,l]naphthacene.

58. The organic light-emitting device of claim 2 wherein the second host component includes a benzoxazolyl moiety or thio and amino analogs of benzoxazolyl moiety.

59. The organic light-emitting device of claim 2 wherein the dopant includes a DCM moiety.

60. The organic light-emitting device of claim 59 wherein the dopant includes DCM, DCJ, DCJT, DCJTE, DCJTP, DCJTBz, DCJTB, or DCJTMes.

61. The organic light-emitting device of claim 2 wherein the dopant includes a periflanthene moiety.

62. The organic light-emitting device of claim 61 wherein the dopant includes Red 2.

63. The organic light-emitting device of claim 2 wherein the dopant includes a coumarin moiety:

64. The organic light-emitting device of claim 63 wherein the dopant includes C-6, C-545T, or C-525T.

65. The organic light-emitting device of claim 2 wherein the dopant includes a quinacridone moiety.

66. The organic light-emitting device of claim 65 wherein the dopant includes QA, DMQA, CFDMQA, or DPQA.

67. The organic light-emitting device of claim 2 wherein the dopant includes a naphthacene moiety.

68. The organic light-emitting device of claim 67 wherein the dopant includes:
5,6,11,12-Tetraphenylnaphthacene (rubrene);
2,2′-[(6,11-diphenyl-5,12-naphthacenediyl)di-4,1-phenylene]bis(6-methylbenzothiazole) (Orange 2);
5,12-Bis(2-mesityl)-6,11-diphenyltetracene;
5,6,11,12-Tetrakis(2-naphthyl)tetracene;
10,10′-[(6,11-Diphenyl-5,12-naphthacenediyl)di-4,1-phenylene]-bis[2,3,6,7-tetrahydro-1H,5H-benzothiazolo[5,6,7-ij]quinolizine;
5,6,13,14-Tetraphenylpentacene;
4,4′-(8,9-Dimethoxy-5,6,7,10,11,12-hexaphenyl-1,4-naphthacenediyl)-bis[N,N-diphenylbenzenamine];
6,11-diphenyl-5,12-bis(4′-N,N-diphenylaminophenyl)naphthacene;
7,8,15,16-Tetraphenyl-benzo[a]pentacene; or
6,11-diphenyl-5,12-bis(4′-cyanophenyl)naphthacene.

69. The organic light-emitting device of claim 2 wherein the dopant includes a BASB moiety.

70. The organic light-emitting device of claim 69 wherein the dopant includes:
4-(Diphenylamino)-4′-[4-(diphenylamino)styryl]stilbene;
4-(Di-p-Tolylamino)-4′-[(di-p-tolylamino)styryl]stilbene (Blue-green 2);
4,4′-[(2,5-Dimethoxy-1,4-phenylene)di-2,1-ethenediyl]bis[N,N-bis(4-methylphenyl)benzenamine;
4,4′-(1,4-Naphthalenediyldi-2,1-ethenediyl)bis[N,N-bis(4-methylphenyl)-benzenamine;
3,3′-(1,4-Phenylenedi-2,1-ethenediyl)bis[9-(4-ethylphenyl)-9H-carbazole;
4,4′-(1,4-Phenylenedi-2,1-ethenediyl)bis[N,N-diphenyl-1-naphthalenamine;
4,4′-[1,4-Phenylenebis(2-phenyl-2,1-ethenediyl)]bis[N,N-diphenyl-benzenamine];
4,4′,4″-(1,2,4-Benzenetriyltri-2,1-ethenediyl)tris[N,N-diphenylbenzenamine];
9,10-Bis[4-(di-p-tolylamino)styryl]anthracene; or
α,α′-(1,4-Phenylenedimethylidyne)bis[4-(diphenylamino)-1-naphthaleneacetonitrile.
